(19) United States
(12) Patent Application Publication
(10) Pub. No.: US 2025/0261548 A1
(43) Pub. Date: Aug. 14, 2025

(54) DISPLAY DEVICE

(71) Applicant: Samsung Display Co., LTD., Yongin-si (KR)

(72) Inventors: Dong Hee SHIN, Yongin-si (KR); Sun Kwun SON, Yongin-si (KR); Na Hyeon CHA, Yongin-si (KR)

(73) Assignee: Samsung Display Co., LTD., Yongin-si (KR)

(21) Appl. No.: 18/934,851

(22) Filed: Nov. 1, 2024

(30) Foreign Application Priority Data
Feb. 8, 2024 (KR) 10-2024-0019604

(51) Int. Cl. H10K 59/80; H10K 59/38

(52) U.S. Cl. CPC H10K 59/8792; H10K 59/38

(57) ABSTRACT

A display device according to an embodiment includes a light emitting element layer including light emitting elements disposed on a substrate, a color filter layer disposed on the light emitting element layer, the color filter layer including color filters disposed in respective emission areas and a first light blocking pattern disposed in a non-emission area surrounding the emission areas, and second light blocking patterns disposed on the light emitting element layer and disposed in the emission areas.

### CROSS-REFERENCE TO RELATED APPLICATION(S)

This application claims priority to and benefits of Korean Patent Application No. 10-2024-0019604 filed on Feb. 8, 2024 under 35 U.S.C. 119, in the Korean Intellectual Property Office, the entire contents of which are incorporated herein by reference.

### BACKGROUND

### 1. Technical Field

Embodiments relate to a display device.

### 2. Description of the Related Art

As the information society develops, the demand for display devices for displaying images has increased and diversified. Accordingly, various types of display devices including light emitting display devices have been developed.

Depending on the use environment of the display device, the visibility of an image displayed on the display device may deteriorate. For example, as external light is reflected from the display device, the visibility of the image may deteriorate.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Aspects of the disclosure provide a display device for which external light reflectivity may be reduced.

However, aspects of the disclosure are not restricted to the ones set forth herein. The above and other aspects will become more apparent to one of ordinary skill in the art to which the disclosure pertains by referencing the detailed description of the disclosure given below.

According to an aspect of the disclosure, there is provided a display device that may include a light emitting element layer including light emitting elements disposed on a substrate; a color filter layer disposed on the light emitting element layer, the color filter layer including color filters disposed in respective emission areas and a first light blocking pattern disposed in a non-emission area surrounding the emission areas and second light blocking patterns disposed on the light emitting element layer and disposed in the emission areas.

In an embodiment, the second light blocking patterns may be at positions spaced apart from the first light blocking pattern, and at least one of the second light blocking patterns may be disposed in each of the emission areas.

In an embodiment, the emission areas may include a first emission area emitting light of a first color, a second emission area emitting light of a second color, and a third emission area emitting light of a third color, and the color filters may include a first color filter disposed in at least the first emission area, a second color filter disposed in at least the second emission area, and a third color filter disposed in at least the third emission area.

In an embodiment, the second light blocking patterns may include color filters of at least two colors that overlap each other at a position where each of the second light blocking patterns is disposed.

In an embodiment, the light of the first color, the light of the second color, and the light of the third color may be red light, green light, and blue light, respectively, the first color filter, the second color filter, and the third color filter may be a red color filter, a green color filter, and a blue color filter, respectively, and each of the second light blocking patterns may include the first color filter and the third color filter.

In an embodiment, each of the second light blocking patterns may further include the second color filter.

In an embodiment, the first light blocking pattern may include the first color filter, the second color filter, and the third color filter that overlap each other in the non-emission area.

In an embodiment, the first light blocking pattern may include a first black matrix pattern disposed in the non-emission area.

In an embodiment, the second light blocking patterns may include at least one second black matrix pattern disposed in each of the emission areas.

In an embodiment, the color filter layer may further include a low refraction layer covering a surface of each of the color filters facing the light emitting element layer, and the second light blocking patterns may include colored spacer patterns disposed on a surface of the low refraction layer.

In an embodiment, the display device may further include a light conversion layer disposed between the light emitting element layer and the color filter layer, the light conversion layer including light transmitting members disposed in the emission areas and a first bank disposed in the non-emission area.

In an embodiment, the second light blocking patterns may include at least one second bank disposed in the light conversion layer and disposed in each of the emission areas to be separated from the first bank, and the first bank and the second bank may include a same material.

In an embodiment, the emission areas may include a first emission area emitting light of a first color, a second emission area emitting light of a second color, and a third emission area emitting light of a third color, and the light transmitting members may include a first light transmitting member disposed in the first emission area, a second light transmitting member disposed in the second emission area, and a third light transmitting member disposed in the third emission area.

In an embodiment, the light emitting elements may emit the light of the third color, the first light transmitting member may include a first wavelength shifter converting the light of the third color into the light of the first color, and the second light transmitting member may include a second wavelength shifter converting the light of the third color into the light of the second color.

In an embodiment, the first light transmitting member, the second light transmitting member, and the third light transmitting member may include a light diffusing agent.

In an embodiment, each of the second light blocking patterns may include at least one of, a first pattern disposed in the light conversion layer, and a second pattern disposed in the color filter layer or between the color filter layer and the light conversion layer.

In an embodiment, each of the second light blocking patterns may further include at least one of, a first reflective film disposed on a surface of the first pattern facing the light emitting element layer, and a second reflective film disposed on a surface of the second pattern facing the light emitting element layer.

According to an aspect of the disclosure, there is provided a display device that may include a light emitting element layer including light emitting elements disposed on a substrate; a light conversion layer disposed on the light emitting element layer, the light conversion layer including light transmitting members disposed in emission areas and a first bank disposed in a non-emission area surrounding the emission areas; a color filter layer disposed on the light conversion layer, the color filter layer including color filters disposed in the emission areas and a first light blocking pattern disposed in the non-emission areas, and second light blocking patterns disposed in at least one of the light conversion layer and the color filter layer and disposed in the emission areas.

In an embodiment, each of the second light blocking patterns may include a second bank disposed in the light conversion layer and separated from the first bank.

In an embodiment, each of the second light blocking patterns may include color filters of at least two colors disposed in the color filter layer and overlapping each other and a black matrix pattern disposed in the color filter layer and separated from the first light blocking pattern or a colored spacer pattern disposed on a surface of a low refraction layer covering a surface of each of the color filters.

A display device according to embodiments may include light blocking patterns disposed in emission areas. According to embodiments, external light reflectivity of the display device may be reduced, and visibility of an image may be improved.

However, effects according to the embodiments of the disclosure are not limited to those described above and various other effects are incorporated herein.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view illustrating a display device according to an embodiment;

FIG. 2 is a schematic plan view illustrating a display panel of FIG. 1;

FIG. 3 is a schematic diagram of an equivalent circuit of a pixel according to an embodiment;

FIG. 4 is a schematic plan view illustrating a display area according to an embodiment;

FIG. 5 is a schematic plan view illustrating a display area according to an embodiment;

FIG. 6 is a schematic plan view illustrating a first color filter of FIG. 4;

FIG. 7 is a schematic plan view illustrating a second color filter of FIG. 4;

FIG. 8 is a schematic plan view illustrating a third color filter of FIG. 4;

FIG. 9 is a schematic plan view illustrating a first bank and a second bank of FIG. 4;

FIG. 10 is a schematic cross-sectional view illustrating the display panel according to an embodiment;

FIG. 11 is a schematic cross-sectional view illustrating the display panel according to an embodiment;

FIG. 12 is a schematic cross-sectional view illustrating the display panel according to an embodiment;

FIG. 13 is an enlarged view of area A1 of FIG. 10;

FIG. 14 is a schematic plan view illustrating a second color filter according to an embodiment;

FIG. 15 is a schematic cross-sectional view illustrating a display panel according to an embodiment;

FIG. 16 is a schematic cross-sectional view illustrating a display panel according to an embodiment;

FIG. 17 is a schematic cross-sectional view illustrating a display panel according to an embodiment;

FIG. 18 is a schematic cross-sectional view illustrating a display panel according to an embodiment;

FIG. 19 is a schematic cross-sectional view illustrating a display panel according to an embodiment;

FIG. 20 is a schematic cross-sectional view illustrating a display panel according to an embodiment;

FIG. 21 is a schematic cross-sectional view illustrating a display panel according to an embodiment; and

FIG. 22 is a schematic cross-sectional view illustrating a display panel according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, sizes, thicknesses, ratios, and dimensions of the elements may be exaggerated for ease of description and for clarity. Like numbers refer to like elements throughout.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will also be understood that when an element or a layer is referred to as being “on” another element or layer, it can be directly on the other element or layer, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “comprises,” “comprising,” “includes,” and/or “including,” “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween.

It will be understood that the terms “connected to” or “coupled to” may include a physical or electrical connection or coupling.

Features of each of various embodiments may be partially or entirely combined with each other and may technically variously interwork with each other, and respective embodiments may be implemented independently of each other or may be implemented together in association with each other.

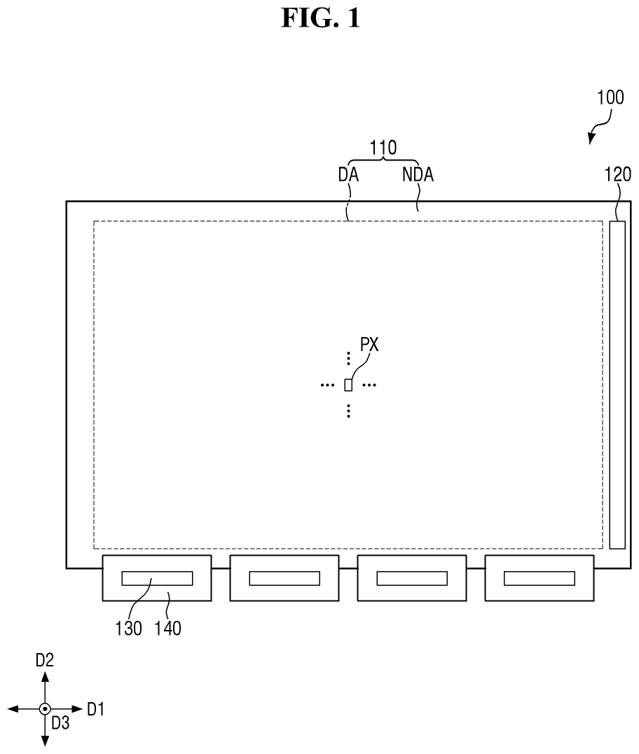

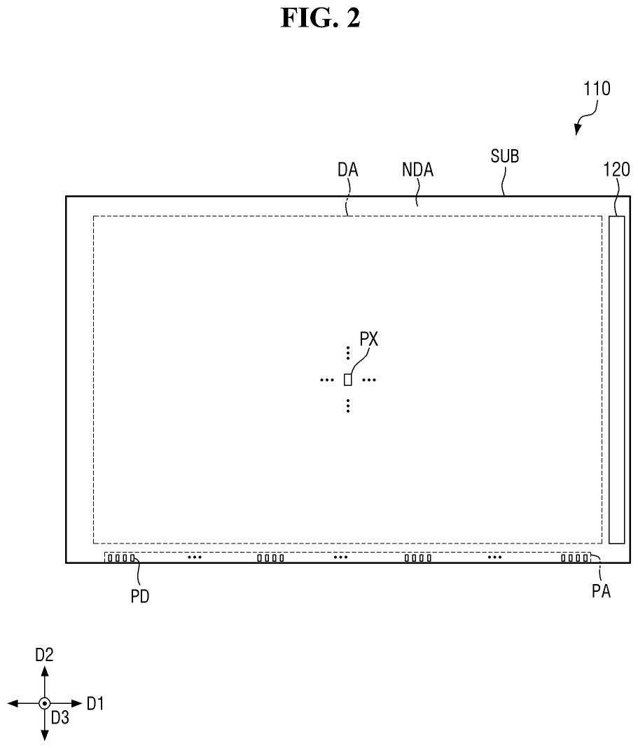

FIG. 1 is a schematic plan view illustrating a display device 100 according to an embodiment. FIG. 2 is a schematic plan view illustrating a display panel 110 of FIG. 1.

Referring to FIGS. 1 and 2, the display device 100 is a device that displays a moving image or a still image, and may be used as a display screen of various products such as televisions, laptop computers, monitors, billboards, and the Internet of Things (IOT) as well as portable electronic devices such as mobile phones, smartphones, tablet personal computers (PCs), smart watches, watch phones, mobile communication terminals, electronic notebooks, electronic books, portable multimedia players (PMPs), navigation devices, and ultra mobile PCs (UMPCs). Such electronic devices are only examples, and the display device 100 may also be adopted in other electronic devices.

In an embodiment, the display device 100 may be a light emitting display device such as an organic light emitting display device including organic light emitting diodes, a quantum dot light emitting display device including quantum dot light emitting layers, an inorganic light emitting display device including inorganic semiconductors, or a micro light emitting display device including micro light emitting diodes such as micro or nano light emitting diodes (micro LEDs or nano LEDs), but is not limited thereto. For example, the display device 100 may also be a type of display device other than the light emitting display device. Hereinafter, embodiments in which the display device 100 is a light emitting display device (for example, an organic light emitting display device) will be disclosed.

The display device 100 may include a display panel 110 including pixels PX, and a first driver 120 and a second driver 130 supplying driving signals to the pixels PX. The display device 100 may further include additional components. For example, the display device 100 may further include a power supply unit for supplying source voltages to the pixels PX, the first driver 120, and the second driver 130, a timing controller for controlling operations of the first driver 120 and the second driver 130, and the like within the spirit and the scope of the disclosure.

The display panel 110 may include a display area DA and a non-display area NDA. The display area DA may be an area displaying an image by including the pixels PX. For example, the display area DA may include pixel areas where the respective pixels PX are disposed. The non-display area NDA is an area other than the display area DA, and an image may not be displayed in the non-display area NDA. In an embodiment, the non-display area NDA may be positioned around the display area DA, and may surround the display area DA.

In FIGS. 1 and 2, a first direction D1, a second direction D2, and a third direction D3 are defined. In an embodiment, the first direction D1 may be a transverse direction of the display panel 110, and the second direction D2 may be a longitudinal direction of the display panel 110. The third direction D3 may be a thickness direction of the display panel 110.

In an embodiment, the display panel 110 may have a rectangular shape in plan view. It has been illustrated in FIGS. 1 and 2 that the display panel 110 has a shape in which a transverse length is greater than a longitudinal length, but a shape of the display panel 110 is not limited thereto. For example, the display panel 110 may have a shape in which the longitudinal length is greater than the transverse length or have a square shape, or the like within the spirit and the scope of the disclosure. The display panel 110 may include angled corners or rounded corners. It is to be understood that the shapes disclosed herein may be substantial to the shapes disclosed.

The shape of the display panel 110 in plan view is not limited to the illustrated rectangular shape, and may also be other shapes. For example, the display panel 110 may have a non-rectangular polygonal shape, a circular shape, an elliptical shape, an irregular shape, or other shapes in plan view.

In an embodiment, the display panel 110 may be substantially flat on a plane defined by the first direction D1 and the second direction D2, and may have a uniform thickness in the third direction D3. By way of example, the display panel 110 may be provided in a three-dimensional shape having a curved surface or the like within the spirit and the scope of the disclosure.

The display panel 110 may be provided as a rigid panel so as not to be substantially deformed or be provided as a flexible panel so as to be deformed, for example, folded, bent, or rolled, in at least a portion thereof. The display panel 110 may be provided in the display device 100 in a state in which it is not bent or provided in the display device 100 in a state in which it is bent in a partial section thereof.

The display panel 110 may include a substrate SUB (for example, a lower substrate) and pixels PX disposed on the substrate SUB. The pixels PX may be disposed in a display area DA on the substrate SUB.

The substrate SUB is a base member for manufacturing or providing the display panel 110, and may constitute a base surface of the display panel 110. The substrate SUB may include a display area DA and a non-display area NDA disposed around the display area DA.

The display area DA may have various shapes according to embodiments. For example, the display area DA may a rectangular shape, a non-rectangular polygonal shape, a circular shape, an elliptical shape, an irregular shape, or other shapes. In an embodiment, the display area DA may have a shape matching the shape of the display panel 110.

The pixels PX may be provided and/or arranged or disposed in the display area DA. For example, the display area DA may include pixel areas where the respective pixels PX are disposed.

In an embodiment, the display device 100 may be a light emitting display device, and each pixel PX may include a light emitting element positioned in each emission area and a pixel circuit connected to the light emitting element. In describing embodiments, the term “connection” may include the meaning of an electrical connection and/or a physical connection. Each pixel circuit may include transistors (for example, transistors including a driving transistor generating a driving current corresponding to a data signal and at least one switching transistor) and at least one capacitor (for example, a storage capacitor).

The non-display area NDA may include a pad area PA where pads PD are disposed. In an embodiment, the non-display area NDA may further include a driving circuit area positioned on at least one side or a side of the display area DA. At least one driver, the pads PD, lines, and the like, may be disposed in the non-display area NDA.

At least one driver for driving the pixels PX or a portion of the driver may be disposed in the driving circuit area. As an example, circuit elements constituting the first driver 120 (for example, driver transistors and driver capacitors constituting stage circuits of the first driver 120) may be disposed in the driving circuit area on the substrate SUB. In an embodiment, the circuit elements of the first driver 120 may be formed in the display panel 110 together with the pixels PX. In an embodiment, the driver transistors provided in the first driver 120 may be transistors whose types and/or structures are substantially the same as or similar to those of transistors provided in the pixels PX, and may be formed simultaneously with the transistors of the pixels PX.

The pads PD may be disposed in the pad area PA. At least one circuit board 140 may be disposed on and/or bonded onto the pad area PA. In an embodiment, circuit boards 140 connected to different pads PD may be disposed on the pad area PA. The pads PD may include signal pads and power pads for transferring driving signals and source voltages required for driving the pixels PX and/or the first driver 120 to the in of the display panel 110.

The first driver 120 and the second driver 130 may generate driving signals for controlling operation timings, luminance, and the like, of the pixels PX, and may supply the driving signals to the pixels PX. For example, the first driver 120 may be a gate driver including a scan driver, and may be connected to the pixels PX through respective gate lines. The first driver 120 may supply respective gate signals (for example, control signals for controlling driving timings of the pixels PX, including scan signals and/or emission control signals) to the pixels PX. The second driver 130 may be a data driver including source driving circuits, and may be connected to the pixels PX through respective data lines. The second driver 130 may supply respective data signals to the pixels PX.

In an embodiment, at least one of the first driver 120 and the second driver 130 or a portion of the at least one driver may be embedded in the display panel 110. For example, the first driver 120 or a portion of the first driver 120 may be disposed on the substrate SUB of the display panel 110 and be disposed and/or formed in the non-display area NDA.

It has been illustrated in FIG. 1 that the first driver 120 is formed in the non-display area NDA on one side or a side of the display area DA (for example, the right side of the display area DA), but embodiments are not limited thereto. For example, the first driver 120 may also be positioned only in the non-display area NDA on the other side of the display area DA (for example, the left side of the display area DA), or be positioned in the non-display areas NDA on both sides of the display area DA (for example, the left side and the right side of the display area DA). By way of example, a portion of the first driver 120 may be positioned in the non-display area NDA, and the other portion of the first driver 120 may be positioned in a non-emission area (for example, an area between emission areas of the pixels PX) in the display area DA.

In an embodiment, the other of the first driver 120 and the second driver 130 or a portion of the other driver may be disposed or formed outside the display panel 110 and electrically connected to the display panel 110. For example, the second driver 130 may be implemented as integrated circuit chips and be disposed on the circuit boards 140 electrically connected to the pixels PX of the display panel 110. The second driver 130 may also be implemented as at least one integrated circuit chip and mounted on the non-display area NDA of the display panel 110.

The circuit board 140 may be connected to the display panel 110 through the pads PD. In an embodiment, the circuit board 140 may be a flexible printed circuit board (FPCB), a printed circuit board (PCB), or a flexible film such as a chip on film (COF), but is not limited thereto. In an embodiment, the circuit board 140 may be connected to the timing controller, the power supply unit, and the like, through another circuit board, a connector, or the like within the spirit and the scope of the disclosure.

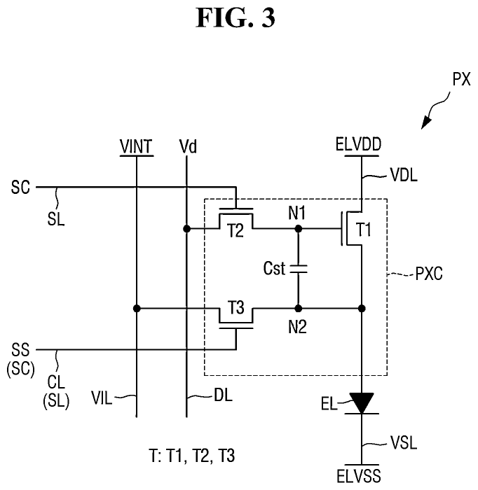

FIG. 3 is a schematic diagram of an equivalent circuit of a pixel PX according to an embodiment. For example, FIG. 3 illustrates a pixel PX of a light emitting display device including a light emitting element EL. A type and/or a structure of the pixel PX that may be included in the display device 100 may be variously changed according to embodiments.

Referring to FIG. 3, the pixel PX may include a light emitting element EL and a pixel circuit PXC connected to the light emitting element EL. The light emitting element EL is a light source of the pixel PX, and may be, for example, an organic light emitting diode, but is not limited thereto. The pixel circuit PXC may control light emission of the light emitting element EL.

The pixel circuit PXC may include transistors T and a capacitor Cst. For example, the pixel circuit PXC may include a first transistor T1, a second transistor T2, and a third transistor T3, and a capacitor Cst. An embodiment in which the transistors T are all N-type transistors has been illustrated in FIG. 3, but types of the transistors T are not limited thereto. For example, at least one transistor T may also be formed as a P-type transistor.

The pixel circuit PXC may supply a driving current to the light emitting element EL in response to the driving signals supplied from the first driver 120 and the second driver 130. For example, the pixel circuit PXC may supply the driving current to the light emitting element EL in response to a scan signal SC and a control signal SS supplied from the first driver 120 through a scan line SL and a control line CL and a data signal Vd supplied from the second driver 130 through a data line DL.

An embodiment in which the scan line SL and the control line CL are separated from each other has been illustrated in FIG. 3, but embodiments are not limited thereto. For example, the control line CL is a portion of the scan line SL, and may branch from the scan line SL, and the control signal SS may be the scan signal SC.

The first transistor T1 may be a driving transistor of the pixel PX whose magnitude of a drain-source current (for example, the driving current) is determined according to its gate-source voltage. The second and third transistors T2 and T3 may be switching transistors that are turned on or off depending on respective gate-source voltages. Depending on a type (for example, a P-type or N-type transistor) and/or an operation condition of each of the transistors, a first electrode of each of the transistors may be a drain electrode (or a drain region) or a source electrode (or a source region), and a second electrode of each of the transistors may be an electrode different from the first electrode. For example, in case that the first electrode is the drain electrode, the second electrode may be the source electrode.

The pixel PX may be connected to the scan line SL transferring the scan signal SC, the control line CL transferring the control signal SS (for example, a sensing control signal or an initialization control signal), and the data line DL transferring the data signal Vd. The pixel PX may be connected to a first power line VDL transferring a first pixel voltage ELVDD (also referred to as a “first pixel source voltage”) and a second power line VSL transferring a second pixel voltage ELVSS (also referred to as a “second pixel source voltage”). A voltage level of the second pixel voltage ELVSS may be lower than a voltage level of the first pixel voltage ELVDD. In an embodiment, the pixel PX may be further connected to an initialization power line VIL transferring an initialization voltage VINT (also referred to as a “third pixel source voltage”).

In an embodiment, the transistors T may be positioned in each pixel area, and may be oxide transistors each including an oxide semiconductor (also referred to as “oxide semiconductor transistors”). For example, an active layer of each of the first, second, and third transistors T1, T2, and T3 may include an oxide semiconductor. However, embodiments are not limited thereto. For example, at least one transistor T may also be made of a semiconductor material (for example, amorphous silicon or polysilicon) other than the oxide semiconductor.

In an embodiment, a light blocking layer, a light blocking electrode (for example, a bottom electrode or a back-gate electrode), or the like, may be disposed below the active layer of at least one of the first, second, and third transistors T1, T2, and T3. As an example, a bottom electrode blocking external light may be disposed below the active layer of the first transistor T1. Accordingly, operation characteristics of the first transistor T1 may be stabilized.

The first transistor T1 may include a gate electrode connected to a first node N1, a first electrode (for example, a drain electrode) connected to the first power line VDL, and a second electrode (for example, a source electrode) connected to a second node N2. The second node N2 may be a node where the pixel circuit PXC and the light emitting element EL are connected to each other. The first transistor T1 may control the driving current of the pixel PX in response to the data signal Vd transferred to the first node N1.

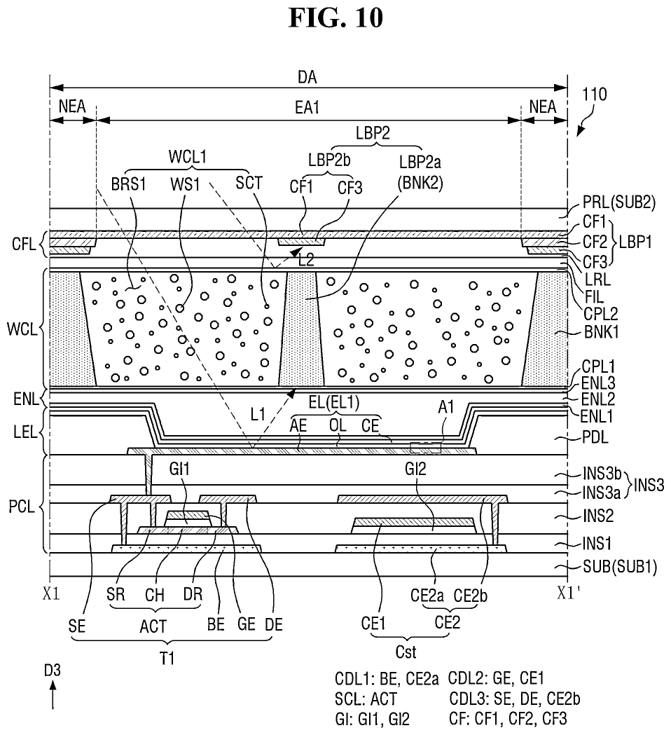

In an embodiment, the first transistor T1 may further include a bottom electrode (for example, a bottom electrode BE in FIG. 10) connected to the second node N2. In case that the first transistor T1 is formed as a transistor having a double-gate structure (for example, a double gate transistor having a source-sync structure) by connecting the bottom electrode of the first transistor T1 to the second node N2, operation characteristics of the first transistor T1 may be improved.

The second transistor T2 may include a gate electrode connected to the scan line SL, a first electrode connected to the data line DL, and a second electrode connected to the first node N1. The second transistor T2 may be turned on by the scan signal SC of a gate-on voltage applied to the scan line SL to connect the data line DL and the first node N1 to each other. Accordingly, the data signal Vd applied to the data line DL may be transferred to the first node N1.

The third transistor T3 may include a gate electrode connected to the control line CL (or the scan line SL), a first electrode connected to the second node N2, and a second electrode connected to the initialization voltage line VIL. The third transistor T3 may be turned on by the control signal SS (or the scan signal SC) of a gate-on voltage applied to the control line CL (or the scan line SL) to connect the initialization voltage line VIL and the second node N2 to each other.

The capacitor Cst may be connected between the first node N1 and the second node N2. The capacitor Cst is a storage capacitor of the pixel PX, and may store a voltage (for example, a difference voltage between a gate voltage and a source voltage of the first transistor T1) corresponding to the data signal Vd (for example, a data voltage) transferred to the first node N1.

The light emitting element EL may be connected between the pixel circuit PXC and the second power line VSL. For example, the light emitting element EL may include a first electrode (for example, an anode electrode) connected to the pixel circuit PXC through the second node N2, a second electrode (for example, a cathode electrode) facing the first electrode and connected to the second power line VSL, and a light emitting layer disposed between the first electrode and the second electrode. In an embodiment, the first electrode of the light emitting element EL may be a pixel electrode provided individually to each pixel PX, and the second electrode of the light emitting element EL may be a common electrode shared by pixels PX. The light emitting element EL may emit light with luminance corresponding to the driving current during a period in which the driving current is supplied from the pixel circuit PXC.

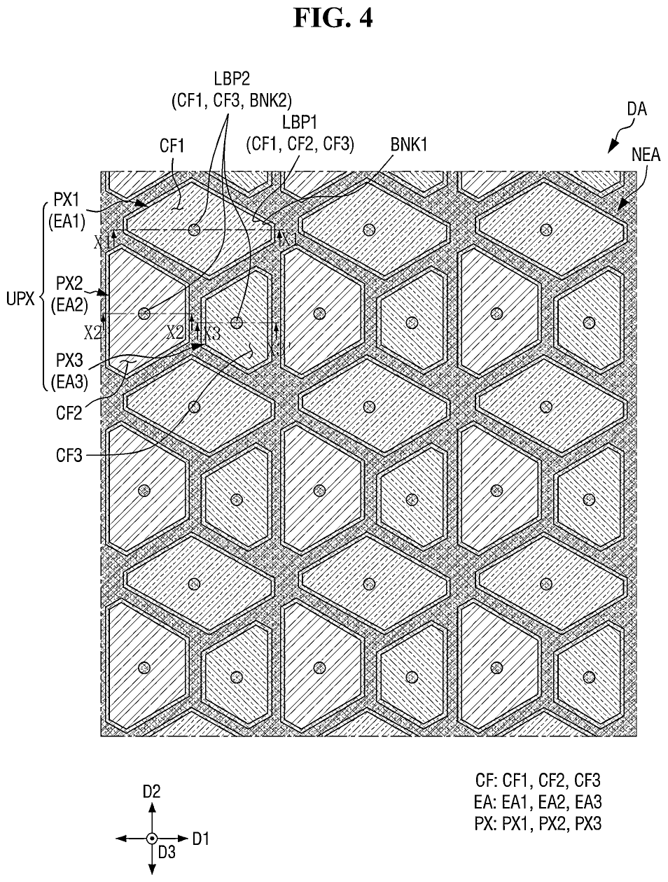

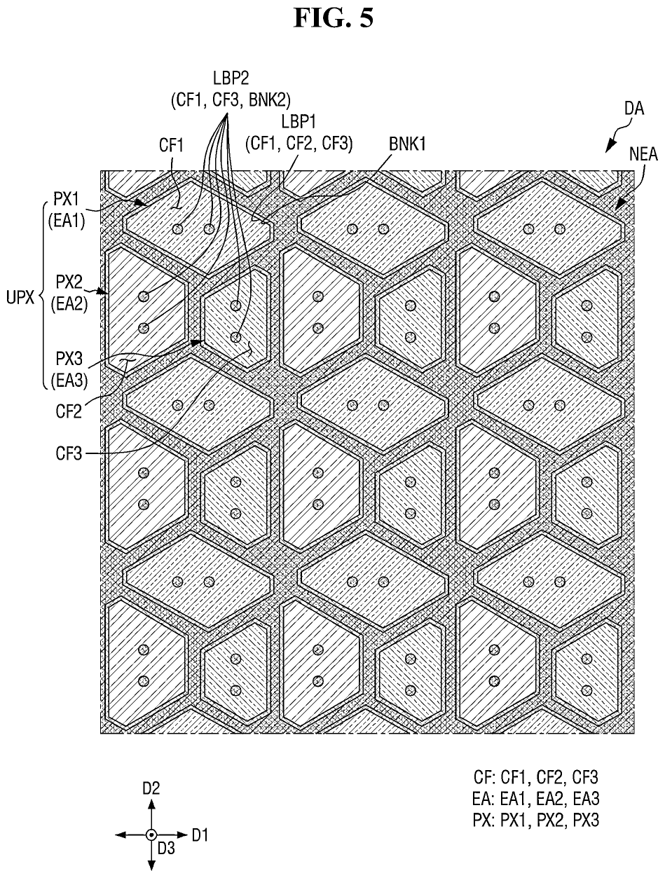

FIG. 4 is a schematic plan view illustrating a display area DA according to an embodiment. FIG. 5 is a schematic plan view illustrating a display area according to an embodiment. For example, FIGS. 4 and 5 illustrate a portion of the display area DA where unit pixels UPX are arranged or disposed, and illustrate different embodiments with respect to second light blocking patterns LBP2.

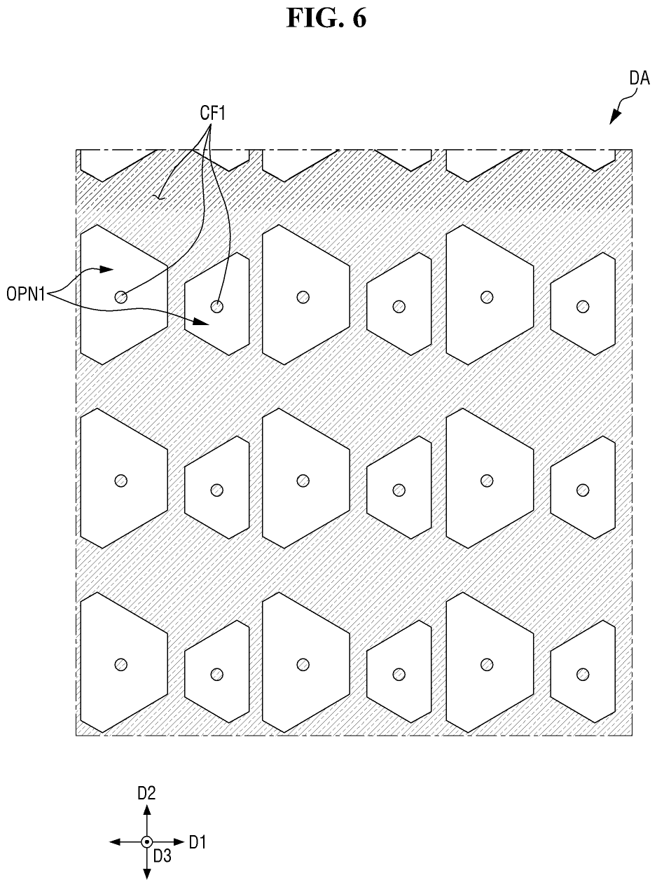

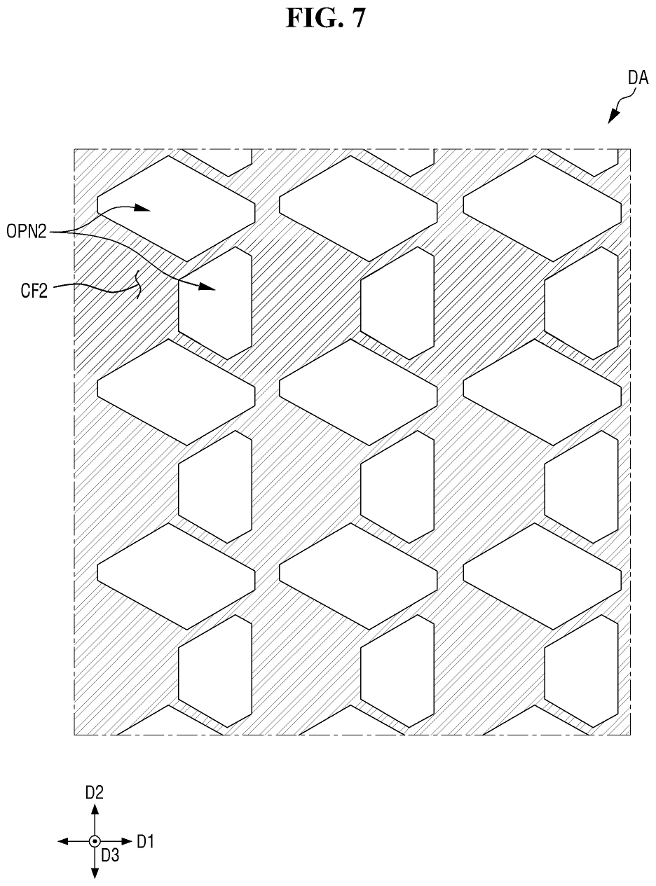

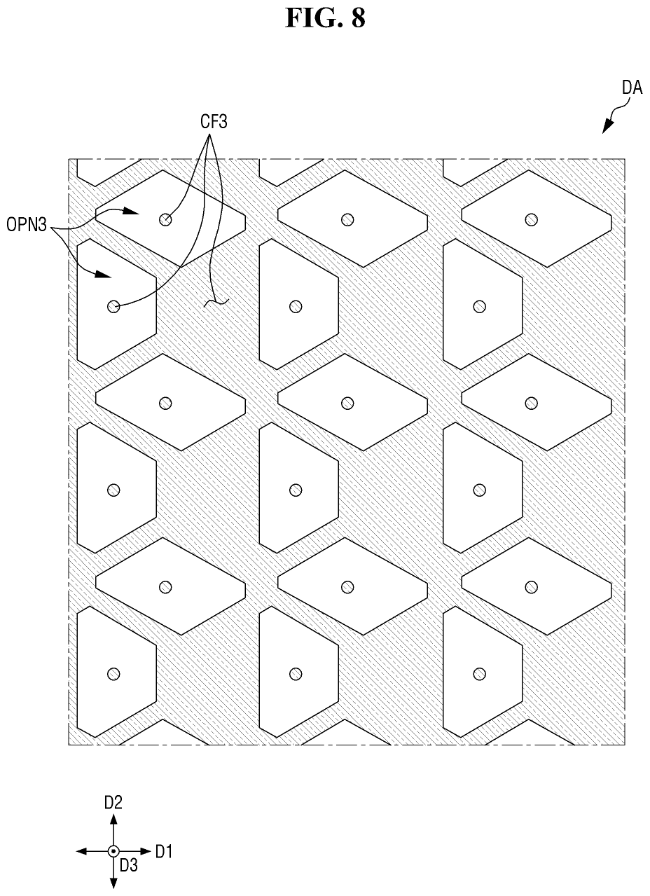

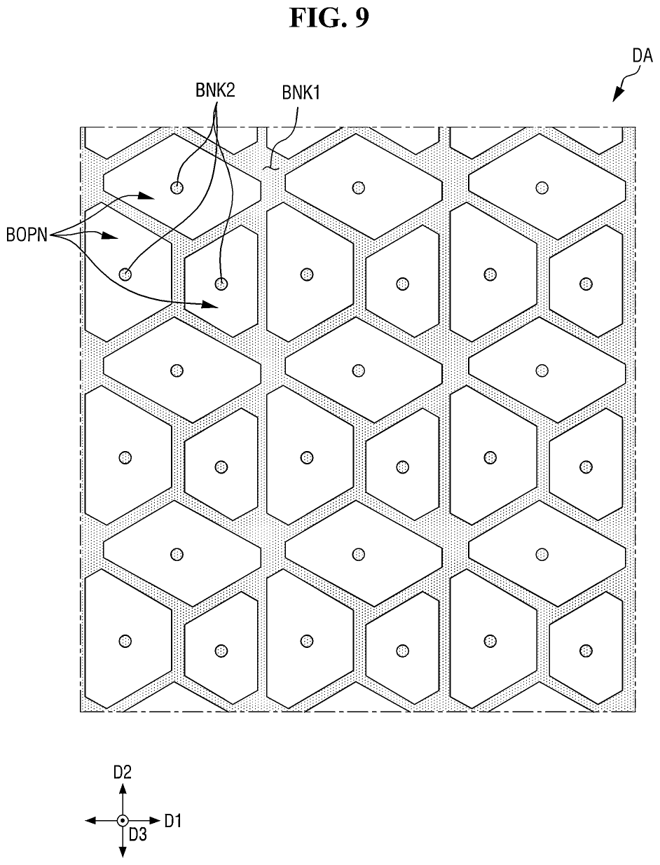

FIG. 6 is a schematic plan view illustrating a first color filter CF1 of FIG. 4. FIG. 7 is a schematic plan view illustrating a second color filter CF2 of FIG. 4. FIG. 8 is a schematic plan view illustrating a third color filter CF3 of FIG. 4. FIG. 9 is a schematic plan view illustrating a first bank BNK1 and a second bank BNK2 of FIG. 4.

Referring to FIGS. 4 to 9 in addition to FIGS. 1 to 3, the display device 100 may include unit pixels UPX arranged or disposed in the display area DA. Each of the unit pixels UPX may include pixels PX emitting light of different colors in each of emission areas EA.

In an embodiment, each unit pixel UPX may include a first pixel PX1 (also referred to as a “first sub-pixel”) emitting light of a first color (for example, red light), a second pixel PX2 (also referred to as a “second sub-pixel”) emitting light of a second color (for example, green light), and a third pixel PX3 (also referred to as a “third sub-pixel”) emitting light of a third color (for example, blue light). An embodiment in which one unit pixel UPX may include one first pixel PX1, one second pixel PX2, and one third pixel PX3 has been disclosed in FIG. 4, but embodiments are not limited thereto. For example, types, the number, ratios, and the like, of pixels PX included in each unit pixel UPX may be variously changed according to embodiments.

Each pixel PX may include each emission area EA where a light emitting element EL (for example, an organic light emitting diode) or the like is disposed. In FIG. 4, a position of each pixel PX has been illustrated based on the emission area EA, but embodiments are not limited thereto. For example, the pixel area where each pixel PX is provided may include an emission area EA where the light emitting element EL or the like is disposed and a pixel circuit area where circuit elements of the pixel circuit PXC are disposed. In an embodiment, the emission area EA and the pixel circuit area of each pixel PX may overlap each other.

The first pixel PX1 may include a first emission area EAl emitting the light of the first color. In an embodiment, the first pixel PX1 may include a light emitting element EL (for example, a red light emitting element) emitting the light of the first color or include a light emitting element EL emitting light of a given color (for example, a third color or a white color), a wavelength shifter converting the light of the given color into the light of the first color, and the like within the spirit and the scope of the disclosure. Accordingly, the light of the first color may be emitted from the first emission area EA1.

The second pixel PX2 may include a second emission area EA2 emitting the light of the second color. In an embodiment, the second pixel PX2 may include a light emitting element EL (for example, a green light emitting element) emitting the light of the second color or include a light emitting element EL emitting light of a given color, a wavelength shifter converting the light of the given color into the light of the second color, and the like within the spirit and the scope of the disclosure. Accordingly, the light of the second color may be emitted from the second emission area EA2.

The third pixel PX3 may include a third emission area EA3 emitting the light of the third color. In an embodiment, the third pixel PX3 may include a light emitting element EL (for example, a blue light emitting element) emitting the light of the third color or include a light emitting element EL emitting light of a given color, a wavelength shifter converting the light of the given color into the light of the third color, and the like within the spirit and the scope of the disclosure. Accordingly, the light of the third color may be emitted from the third emission area EA3.

Each of the emission areas EA may have a quadrangular shape, a non-quadrangular polygonal shape, a circular shape, an elliptical shape, or other shapes. The emission areas EA may have substantially the same shape and size or have different shapes and/or sizes.

For example, depending on various factors such as aperture ratios, transmissivity, luminous efficiency, and visibility of the first pixel PX1, the second pixel PX2, and the third pixel PX3 or white balance of the unit pixel UPX, shapes, sizes, ratios, arrangement forms, and the like, of the first emission area EA1, the second emission area EA2, and the third emission area EA3 may be determined or changed. In an embodiment, the first emission area EA1 and the second emission area EA2 may have the same size or similar sizes, and the third emission area EA3 may have a smaller size than the first emission area EAl and the second emission area EA2, but the disclosure is not limited thereto.

In an embodiment, color filters CF transmitting light of colors to be emitted from the respective pixels PX therethrough may be disposed in the emission areas EA. For example, a first color filter CF1 (for example, a red color filter) transmitting the light of the first color therethrough may be disposed in the first emission area EA1. A second color filter CF2 (for example, a green color filter) transmitting the light of the second color therethrough may be disposed in the second emission area EA2. A third color filter CF3 (for example, a blue color filter) transmitting the light of the third color therethrough may be disposed in the third emission area EA3.

The display area DA may further include a non-emission area NEA in addition to the emission areas EA of the pixels PX. The non-emission area NEA may surround the emission areas EA. For example, the non-emission area NEA may be disposed around the emission areas EA so as to surround each of the emission areas EA.

A first light blocking pattern LBP1 may be disposed in the non-emission area NEA. In an embodiment, the first light blocking pattern LBP1 may include color filters CF of at least two colors overlapping each other. As an example, the first light blocking pattern LBP1 may include the first color filter CF1, the second color filter CF2, and the third color filter CF3 that are disposed to overlap each other in the non-emission area NEA.

For example, portions (for example, filtering pattern portions) of the first color filter CF1 may be disposed in the first emission areas EA1, and the other portions (for example, light blocking pattern portions) of the first color filter CF1 may be disposed in the non-emission area NEA. The first color filter CF1 may include first openings OPNI corresponding to the second emission areas EA2 and the third emission areas EA3.

Portions (for example, filtering pattern portions) of the second color filter CF2 may be disposed in the second emission areas EA2, and the other portions (for example, light blocking pattern portions) of the second color filter CF2 may be disposed in the non-emission area NEA. The second color filter CF2 may include second openings OPN2 corresponding to the first emission areas EAl and the third emission areas EA3.

Portions (for example, filtering pattern portions) of the third color filter CF3 may be disposed in the third emission areas EA3, and the other portions (for example, light blocking pattern portions) of the third color filter CF3 may be disposed in the non-emission area NEA. The third color filter CF3 may include third openings OPN3 corresponding to the first emission areas EA1 and the second emission areas EA2.

The first bank BNK1 overlapping the first light blocking pattern LBP1 (for example, overlapping the first light blocking pattern LBP1 in the third direction D3) may be further disposed in the non-emission area NEA. In an embodiment, the first bank BNK1 may be disposed below the first light blocking pattern LBP1. For example, the first light blocking pattern LBP1 may be provided in a color filter layer including the color filters CF, and the first bank BNK1 may be provided in a light conversion layer disposed below the color filter layer. The first bank BNK1 may include openings BOPN corresponding to the first emission areas EA1, the second emission areas EA2, and the third emission areas EA3. In an embodiment, the openings BOPN of the first bank BNK1 may have greater sizes than the respective emission areas EA and expose the emission areas EA.

The display device 100 according to embodiments may further include second light blocking patterns LBP2 disposed in the emission areas EA. For example, at least one second light blocking pattern LBP2 may be disposed in each of the emission areas EA.

As an example, one second light blocking pattern LBP2 may be disposed in each of the emission areas EA as illustrated in FIG. 4 or two second light blocking patterns LBP2 may be disposed in each of the emission areas EA as illustrated in FIG. 5. The number of second light blocking patterns LBP2 disposed in each of the emission areas EA may be changed according to embodiments. For example, three or more second light blocking patterns LBP2 may be disposed in at least one emission area EA. The same number of second light blocking patterns LBP2 or different numbers of second light blocking patterns LBP2 may be disposed in the first emission area EA1, the second emission area EA2, and the third emission area EA3. In an embodiment, the second light blocking pattern LBP2 may not be disposed in at least one emission area EA of the first emission area EA1, the second emission area EA2, and the third emission area EA3, and the second light blocking patterns LBP2 may be disposed only in the other emission areas EA.

In an embodiment, the second light blocking patterns LBP2 may be disposed at positions spaced apart from the first light blocking pattern LBP1. For example, each second light blocking pattern LBP2 may be positioned at the center (for example, in an area including a central portion) of each emission area EA. As an example, each second light blocking pattern LBP2 may be an island-shaped pattern that is separated from the first light blocking pattern LBP1 and individually disposed.

Each second light blocking pattern LBP2 may be disposed on the light emitting element EL of each pixel PX. For example, the second light blocking patterns LBP2 may be disposed on a light emitting element layer including the light emitting element EL of each pixel PX.

In an embodiment, the second light blocking patterns LBP2 may be disposed in the color filter layer and the light conversion layer. As an example, each of the second light blocking patterns LBP2 may include at least color filters CF of at least two colors (for example, the first color filter CF1 and the third color filter CF3) and the second bank BNK2 disposed to overlap each other at a position where each of the second light blocking patterns LBP2 is disposed. In an embodiment, the first bank BNK1 and the second bank BNK2 may be patterns formed simultaneously using the same material, and may be separated from each other. For example, the second bank BNK2 may be disposed to be separated from the first bank BNK1 in a light conversion layer WCL in which the first bank BNK1 is provided, and may include the same material as the first bank BNK1. In an embodiment, the second bank BNK2 may be disposed below the color filters CF of at least two colors constituting each second light blocking pattern LBP2.

Structures and positions of the second light blocking patterns LBP2 may be changed according to embodiments. For example, the second light blocking patterns LBP2 may also be disposed in only one of the color filter layer and the light conversion layer. As an example, the second light blocking patterns LBP2 may include the color filters CF of at least two colors, but may not include the second bank BNK2. By way of example, the second light blocking patterns LBP2 may include the second bank BNK2, but may not include the color filters CF of at least two colors.

According to embodiments, reflection of external light may be blocked or reduced by disposing at least one second light blocking pattern LBP2 in the emission area EA of each pixel PX. Accordingly, external light reflectivity of the display device 100 may be reduced.

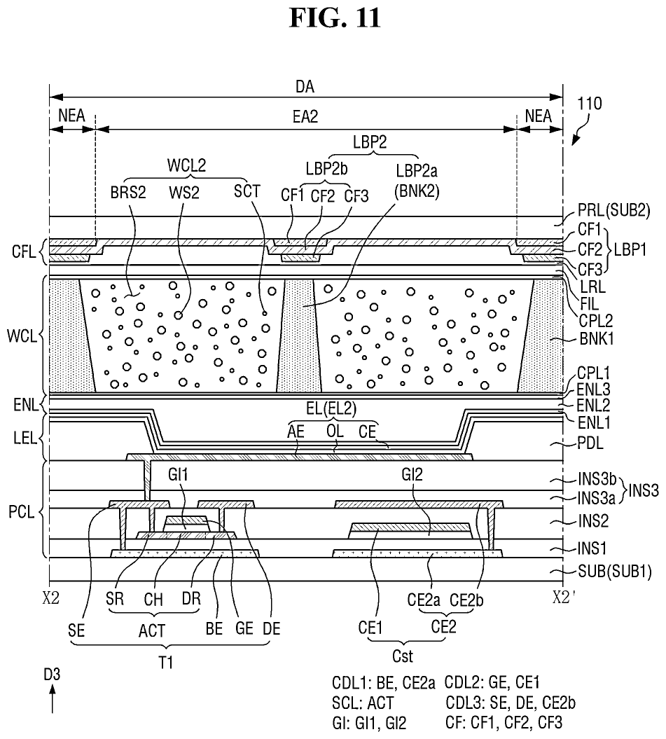

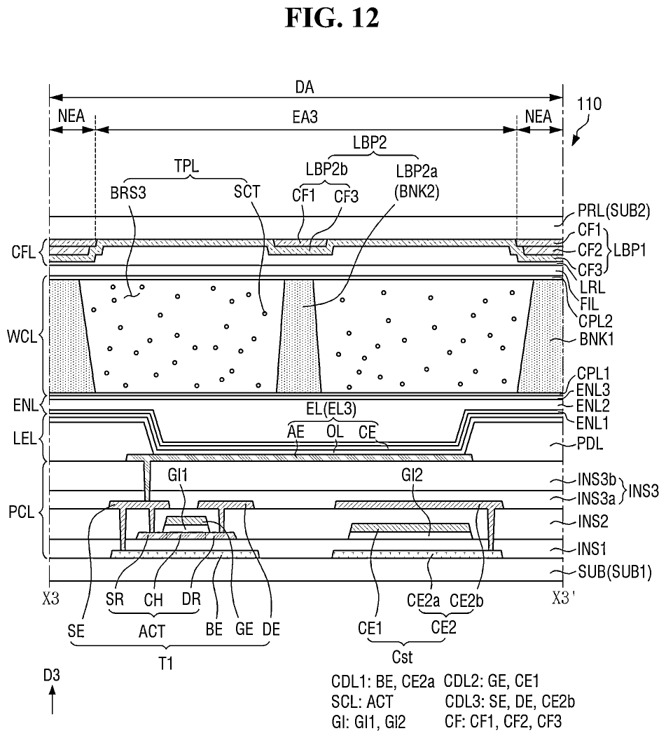

FIG. 10 is a schematic cross-sectional view illustrating the display panel 110 according to an embodiment. FIG. 11 is a schematic cross-sectional view illustrating the display panel 110 according to an embodiment. FIG. 12 is a schematic cross-sectional view illustrating the display panel 100 according to an embodiment. For example, FIGS. 10, 11, and 12 illustrate an embodiment of a cross section of the first pixel PX1 corresponding to line X1-X1′ of FIG. 4, a cross section of the second pixel PX2 corresponding to line X2-X2′ of FIG. 4, and a cross section of the third pixel PX3 corresponding to line X3-X3′ of FIG. 4, respectively. FIGS. 10 and 12 illustrate a light emitting display panel including light emitting elements EL (for example, tandem organic light emitting diodes) as an example of the display panel 110 to which embodiments may be applied.

Referring to FIGS. 10 to 12 in addition to FIGS. 1 to 9, the display panel 110 may include a substrate SUB (or a lower substrate SUB1), a panel circuit layer PCL, a light emitting element layer LEL, an encapsulation layer ENL, a light conversion layer WCL, a color filter layer CFL, and a protective layer PRL. The panel circuit layer PCL, the light emitting element layer LEL, the encapsulation layer ENL, the light conversion layer WCL, the color filter layer CFL, and the protective layer PRL may be disposed to overlap each other on the substrate SUB. As an example, the panel circuit layer PCL, the light emitting element layer LEL, the encapsulation layer ENL, the light conversion layer WCL, the color filter layer CFL, and the protective layer PRL may be sequentially disposed on the substrate SUB along the third direction D3. Positions, configurations, or the like, of the panel circuit layer PCL, the light emitting element layer LEL, the encapsulation layer ENL, the light conversion layer WCL, the color filter layer CFL, and/or the protective layer PRL may be changed according to embodiments.

In an embodiment, the protective layer PRL may be an upper substrate SUB2, and at least one of the light conversion layer WCL and the color filter layer CFL may be formed on the upper substrate SUB2. As an example, the lower substrate SUB1 on which the panel circuit layer PCL, the light emitting element layer LEL, the encapsulation layer ENL, the light conversion layer WCL, and the like, are formed and the upper substrate SUB2 on which the color filter layer CFL is formed may be bonded to each other with a filler FIL disposed therebetween.

The substrate SUB is a base member for forming the display panel 110, and may be a rigid or flexible substrate (or film). In an embodiment, the substrate SUB may be a substrate including an insulating material such as glass and having rigid characteristics, and may not be bent. By way of example, the substrate SUB may be a flexible substrate including polyimide or other insulating materials and capable of being deformed, for example, bent, folded, or rolled, and may or may not be bent. A type and/or a material of the substrate SUB may be changed according to embodiments.

The panel circuit layer PCL (for example, a pixel circuit layer or a thin film transistor layer) may be disposed on the substrate SUB. The panel circuit layer PCL may include circuit elements including transistors T and capacitors Cst of the pixels PX, and lines (for example, signal lines and power lines). In an embodiment, the panel circuit layer PCL may further include circuit elements of the first driver 120 (for example, driver transistors and/or driver capacitors provided in the first driver 120) and/or additional conductive patterns (for example, bridge patterns).

FIGS. 10 to 12 illustrate a first transistor T1 and a capacitor Cst of each pixel PX as examples of the circuit elements that may be provided in the panel circuit layer PCL. An embodiment in which the panel circuit layer PCL is disposed directly on the substrate SUB has been illustrated in FIGS. 10 to 12, but embodiments are not limited thereto. For example, the display panel 110 may further include a barrier layer disposed on the substrate SUB, and the panel circuit layer PCL may be disposed on the barrier layer.

The panel circuit layer PCL may include conductive layers and at least one semiconductor layer SCL. In the conductive layers, electrodes constituting the circuit elements (for example, the transistors T and the capacitor Cst constituting each pixel circuit PXC) of the panel circuit layer PCL, conductive patterns (for example, bridge electrodes) connected to the circuit elements, lines, and the like, may be provided. In the semiconductor layer SCL, active layers ACT of the transistors T provided in the panel circuit layer PCL may be provided.

In an embodiment, the panel circuit layer PCL may include a first conductive layer CDL1 (for example, a bottom conductive layer), the semiconductor layer SCL, a second conductive layer CDL2 (for example, a gate conductive layer), and a third conductive layer CDL3 (for example, a source-drain conductive layer or a data conductive layer) that are sequentially disposed on the substrate SUB along the third direction D3. In an embodiment, the panel circuit layer PCL may further include at least one conductive layer disposed on the third conductive layer CDL3 and at least one insulating layer covering the at least one conductive layer. The at least one conductive layer may include a bridge electrode connecting the light emitting element EL and the pixel circuit PXC (for example, the first transistor T1) of each pixel PX to each other, at least one line, and the like within the spirit and the scope of the disclosure.

Patterns included in each conductive layer of the panel circuit layer PCL (for example, electrodes, conductive patterns, and/or lines of each conductive layer) may each include a conductive material. For example, the patterns provided in each of the first conductive layer CDL1, the second conductive layer CDL2, and the third conductive layer CDL3 may each include at least one of copper (Cu), titanium (Ti), molybdenum (Mo), aluminum (Al), chromium (Cr), gold (Au), silver (Ag), platinum (Pt), palladium (Pd), nickel (Ni), neodymium (Nd), iridium (Ir), tantalum (Ta), tungsten (W), magnesium (Mg), and other metals, alloys thereof, or other conductive materials. In an embodiment, patterns included in the same conductive layer may be formed simultaneously using the same conductive material.

In an embodiment, the respective patterns provided in each conductive layer of the panel circuit layer PCL may have a single-layer or multilayer structure. For example, the patterns provided in the first conductive layer CDL1, the second conductive layer CDL2, and the third conductive layer CDL3, respectively, may each have a single-layer or multilayer structure. In an embodiment, the patterns included in the same conductive layer may have the same cross-sectional structure.

The panel circuit layer PCL may further include insulating layers and/or insulating patterns disposed on the substrate SUB. For example, the panel circuit layer PCL may include a first insulating layer INS1, a gate insulating layer GI, a second insulating layer INS2, and a third insulating layer INS3 that are sequentially disposed on the substrate SUB along the third direction D3.

In an embodiment, at least one insulating layer provided in the panel circuit layer PCL may be entirely disposed in the display area DA. For example, the first insulating layer INS1, the second insulating layer INS2, and the third insulating layer INS3 may be entirely disposed in the display area DA.

The first insulating layer INS1 may be disposed on the first conductive layer CDL1. For example, the first insulating layer INS1 may be disposed on the substrate SUB and cover the patterns of the first conductive layer CDL1. The first insulating layer INS1 may include at least one inorganic insulating layer including an inorganic insulating material (for example, silicon nitride, silicon oxide, silicon oxynitride, titanium oxide, aluminum oxide, or other inorganic insulating materials).

The gate insulating layer GI may be disposed on the first insulating layer INS1 and the semiconductor layer SCL. The gate insulating layer GI may cover a portion of each of the first insulating layer INS1 and the semiconductor layer SCL. The gate insulating layer GI may include at least one inorganic insulating layer including an inorganic insulating material.

In an embodiment, the gate insulating layer GI may be partially disposed only in each pixel area and a portion of the display area DA including each pixel area. In an embodiment, the gate insulating layer GI may include a first gate insulating layer GI1 (also referred to as a “first gate insulating pattern”) that is disposed on a portion of each active layer ACT provided in the semiconductor layer SCL and a second gate insulating layer GI2 (also referred to as a “second gate insulating pattern”) that is disposed on the first insulating layer INS1 and does not overlap the active layer ACT. For example, the first gate insulating layer GI1 may be disposed between a portion of the active layer ACT including a channel region CH and a gate electrode GE, and the second gate insulating layer GI2 may be disposed between the first insulating layer INS1 and a first capacitor electrode CE1. The first gate insulating layer GI1 and the second gate insulating layer GI2 may be an integrated insulating pattern connected to each other in plan view or be individual insulating patterns separated from each other. However, embodiments are not limited thereto. For example, the gate insulating layer GI may also be entirely disposed in the display area DA so as to entirely cover the first insulating layer INS1 and the semiconductor layer SCL.

The second insulating layer INS2 may be disposed on the first insulating layer INS1, the semiconductor layer SCL, the gate insulating layer GI, and the second conductive layer CDL2. For example, the second insulating layer INS2 may be disposed on the first insulating layer INS1 and cover the semiconductor layer SCL, the gate insulating layer GI, and the patterns of the second conductive layer CDL2. The second insulating layer INS2 may include at least one inorganic insulating layer including an inorganic insulating material.

The third insulating layer INS3 may be disposed on the third conductive layer CDL3. For example, the third insulating layer INS3 may be disposed on the second insulating layer INS2 and cover the patterns of the third conductive layer CDL3.

The third insulating layer INS3 may include at least one organic insulating layer including an organic insulating material (for example, an acrylic resin, an epoxy resin, a phenolic resin, a polyamide resin, a polyimide resin, or other organic insulating materials). The third insulating layer INS3 may include an inorganic insulating layer or may not include an inorganic insulating layer.

In an embodiment, the third insulating layer INS3 may be formed as multiple layers including a first layer INS3a and a second layer INS3b that are sequentially disposed on the second insulating layer INS2 and the third conductive layer CDL3. The first layer INS3a of the third insulating layer INS3 may be an inorganic insulating layer including an inorganic insulating material. The second layer INS3b of the third insulating layer INS3 may be an organic insulating layer including an organic insulating material. A surface of the third insulating layer INS3 (for example, an upper surface of the second layer INS3b) may be substantially flat.

The first transistor T1 may include an active layer ACT and a gate electrode GE (for example, a top-gate electrode) disposed on a portion of the active layer ACT. In an embodiment, the first transistor T1 may further include at least one of a source electrode SE and a drain electrode DE. For example, the first transistor T1 may further include a source electrode SE connected to a source region SR of the active layer ACT and a drain electrode DE connected to a drain region DR of the active layer ACT. By way of example, the first transistor T1 may not include a separate source electrode and/or drain electrode, and the source region SR and/or the drain region DR of the active layer ACT may be connected to other circuit elements, lines, conductive patterns, and the like, to function as a source electrode and/or a drain electrode of the first transistor T1.

In an embodiment, the first transistor T1 may further include a bottom electrode BE (or a light blocking layer) disposed below the active layer ACT. In an embodiment, the bottom electrode BE may be connected to one electrode (for example, the source electrode SE or the gate electrode GE) of the first transistor T1, and may be utilized as a back-gate electrode BG adjusting characteristics of the first transistor T1. As an example, the bottom electrode BE may be connected to the source electrode SE of the first transistor T1 through at least one contact hole penetrating through the first insulating layer INS1 and the second insulating layer INS2. By disposing the bottom electrode BE below the active layer ACT, external light incident on the channel region CH or the like of the active layer ACT may be blocked, and operation characteristics of the first transistor T1 may be stabilized.

In an embodiment, the first transistor T1 may be an oxide transistor. As an example, the first transistor T1 may be an N-type oxide transistor.

The bottom electrode BE may be provided in the first conductive layer CDL1 disposed on the substrate SUB. The first conductive layer CDL1 may be covered with the first insulating layer INS1.

The bottom electrode BE may overlap the active layer ACT and the gate electrode GE. For example, the bottom electrode BE may be disposed below the active layer ACT so as to overlap at least a portion of the active layer ACT including the channel region CH, and may face the gate electrode GE with the active layer ACT disposed therebetween.

The active layer ACT may be provided in the semiconductor layer SCL. The semiconductor layer SCL may be disposed on the first insulating layer INS1, and may be covered by the gate insulating layer GI and the second insulating layer INS2.

The active layer ACT may include the channel region CH and the source region SR and the drain region DR spaced apart from each other with the channel region CH disposed therebetween. For example, the source region SR and the drain region DR may be positioned on both sides of the channel region CH, respectively. The source region SR and the drain region DR may be regions made to be conductive so as to have a higher carrier concentration (for example, electron concentration) than the channel region CH.

The active layer ACT may overlap the bottom electrode BE and the gate electrode GE. For example, a portion of the active layer ACT including the channel region CH may overlap the bottom electrode BE and the gate electrode GE in the third direction D3.

In an embodiment, the active layer ACT may include an oxide semiconductor. For example, the active layer ACT may include an oxide semiconductor including at least one of indium (In), gallium (Ga), zinc (Zn), tin (Sn), and hafnium (Hf), or other oxide semiconductors. As an example, the active layer ACT may include at least one of zinc oxide (ZnO), zinc tin oxide (ZTO), indium zinc oxide (IZO), indium oxide (InO or In₂O₃), titanium oxide (TiO or TiO₂), indium gallium oxide (IGO), indium gallium zinc oxide (IGZO), indium gallium tin oxide (IGTO), indium zinc tin oxide (IZTO), and indium tin gallium zinc oxide (ITGZO), or other oxide semiconductors.

The first gate insulating layer GII may be disposed on the active layer ACT. For example, the first gate insulating layer GII may be disposed between the active layer ACT and the gate electrode GE.

In an embodiment, the first gate insulating layer GIl may cover a portion of the active layer ACT including a portion overlapping the gate electrode GE and expose the other portion of the active layer ACT. As an example, the first gate insulating layer GI1 may be disposed on a portion of the active layer ACT including the channel region CH, and may expose the source region SR and the drain region DR of the active layer ACT.

As the first gate insulating layer GI1 exposes the source region SR and the drain region DR, the source region SR and the drain region DR may be appropriately and/or readily made to be conductive in a manufacturing process of the display panel 110. For example, in a process of etching the gate insulating layer GI so as to expose at least a portion of each of the source region SR and drain region DR, oxygen vacancies may occur in the source region SR and drain region DR. Accordingly, the source region SR and drain region DR may be appropriately made to be conductive in a subsequent process (for example, a process of forming the second insulating layer INS2) without performing a separate doping process.

The gate electrode GE may be disposed on the first gate insulating layer GI1. The gate electrode GE may be provided in the second conductive layer CDL2. The second conductive layer CDL2 may be disposed on the first insulating layer INS1 and the gate insulating layer GI, and may be covered by the second insulating layer INS2.

The gate electrode GE may be disposed on the active layer ACT. For example, the gate electrode GE may be disposed on the first gate insulating layer GI1 covering the channel region CH of the active layer ACT. The gate electrode GE and the active layer ACT may be separated from each other with the first gate insulating layer GIl disposed therebetween.

The second insulating layer INS2 may be disposed on the gate electrode GE. The second insulating layer INS2 may cover the first insulating layer INS1, the active layer ACT, the gate insulating layer GI, and the second conductive layer CDL2.

The source electrode SE and the drain electrode DE may be disposed on the second insulating layer INS2. The source electrode SE and drain electrode DE may be provided in the third conductive layer CDL3. The third conductive layer CDL3 may be disposed between the second insulating layer INS2 and the third insulating layer INS3.

The source electrode SE may be connected to a portion of the active layer ACT. For example, the source electrode SE may be electrically connected to the source region SR of the active layer ACT through at least one contact hole penetrating through the second insulating layer INS2. In an embodiment, the source electrode SE may also be electrically connected to the bottom electrode BE.

The drain electrode DE may be connected to another portion of the active layer ACT. For example, the drain electrode DE may be connected to the drain region DR of the active layer ACT through at least one contact hole penetrating through the second insulating layer INS2.

The first transistor T1 of each pixel PX may be electrically connected to the light emitting element EL of each pixel PX. For example, the first transistor T1 disposed in each pixel area may be electrically connected to a first electrode AE of a light emitting element EL disposed in each pixel area in the light emitting element layer LEL.

The capacitor Cst may include capacitor electrodes forming capacitance. As an example, the capacitor Cst may include a first capacitor electrode CE1 and a second capacitor electrode CE2.

In an embodiment, the capacitor Cst may include a multilayer electrode. For example, at least one of the first capacitor electrode CE1 and the second capacitor electrode CE2 may have a multilayer structure including sub-electrodes.

In an embodiment, the first capacitor electrode CE1 may be a single-layer electrode provided in the second conductive layer CDL2. However, embodiments are not limited thereto. For example, the first capacitor electrode CE1 may further include at least one sub-electrode provided in another conductive layer.

In an embodiment, the first capacitor electrode CE1 may be connected to the gate electrode GE of the first transistor T1 positioned in each pixel area. As an example, the first capacitor electrode CE1 may be provided in the second conductive layer CDL2 integral with the gate electrode GE of the first transistor T1. For example, the first capacitor electrode CE1 and the gate electrode GE of the first transistor T1 may be formed as an integrated electrode connected to each other when viewed on a plane defined by the first direction D1 and the second direction D2. In this case, the first gate insulating layer GI1 positioned beneath the gate electrode GE of the first transistor T1 and the second gate insulating layer GI2 positioned beneath the first capacitor electrode CE1 may be connected to each other.

In an embodiment, the second capacitor electrode CE2 may include a first sub-electrode CE2a provided in the first conductive layer CDL1 and a second sub-electrode CE2b provided in the third conductive layer CDL3. The first sub-electrode CE2a and the second sub-electrode CE2b of the second capacitor electrode CE2 may overlap the first capacitor electrode CE1. The first sub-electrode CE2a and the second sub-electrode CE2b of the second capacitor electrode CE2 may be electrically connected to each other through at least one contact hole penetrating through the first insulating layer INS1 and the second insulating layer INS2. The second capacitor electrode CE2 is formed in a multilayer structure, and accordingly, capacitance of the capacitor Cst may be appropriately secured by efficiently utilizing the pixel area having a limited size.

In an embodiment, the second capacitor electrode CE2 may be formed as a single electrode provided in the first conductive layer CDL1 or the third conductive layer CDL3. By way of example, the second capacitor electrode CE2 may be formed as a triple-layer or more electrodes further including at least one sub-electrode provided in another conductive layer (for example, a fourth conductive layer additionally formed between the third insulating layer INS3 and the light emitting element layer LEL).

In an embodiment, the second capacitor electrode CE2 may be connected to the source electrode SE of the first transistor T1 positioned in each pixel area. As an example, the first sub-electrode CE2a of the second capacitor electrode CE2 may be provided in the first conductive layer CDL1 integral with the bottom electrode BE of the first transistor T1, and may be connected to the source electrode SE of the first transistor T1 through at least one contact hole. The second sub-electrode CE2b of the second capacitor electrode CE2 may be integral with or separately from the source electrode SE of the first transistor T1 positioned in each pixel area.

The light emitting element layer LEL may be disposed on the panel circuit layer PCL. For example, the light emitting element layer LEL may be disposed on the third insulating layer INS3, and may be positioned at least in the display area DA.

The light emitting element layer LEL may include a light emitting element EL of each of the pixels PX. For example, the light emitting element layer LEL may include light emitting elements EL disposed in the emission areas EA of the pixels PX and a pixel defining film PDL disposed around the light emitting elements EL. When viewed on the plane defined by the first direction D1 and the second direction D2, the pixel defining film PDL may surround the light emitting element EL of each pixel PX.

Each light emitting element EL may include a first electrode AE positioned in each emission area EA and a light emitting layer OL and a second electrode CE that are sequentially disposed on the first electrode AE. One of the first electrode AE and the second electrode CE of the light emitting element EL may be an anode electrode, and the other of the first electrode AE and the second electrode CE of the light emitting element EL may be a cathode electrode. As an example, the first electrode AE may be an anode electrode, and the second electrode CE may be a cathode electrode.

In an embodiment, the first electrode AE may be a pixel electrode formed individually for each emission area EA. The first electrode AE may be connected to at least one transistor T (for example, the first transistor T1) included in the corresponding pixel PX.

In an embodiment, the display panel 110 may be a top emission-type display panel, and the first electrode AE may include a metal layer including a metal such as Ag, Mg, Al, Pt, Pd, Au, Ni, Nd, Ir, or Cr. In an embodiment, the first electrode AE may further include a metal oxide layer overlapping the metal layer. As an example, the first electrode AE may have a double-layer structure of indium tin oxide (ITO)/Ag, Ag/ITO, ITO/Mg, or ITO/MgF or a triple-layer structure such as ITO/Ag/ITO.

The pixel defining film PDL may be disposed on the first electrodes AE of the light emitting elements EL. For example, the pixel defining film PDL may be disposed on portions of the first electrodes AE. As an example, the pixel defining film PDL may cover an edge portion of the first electrode AE positioned in each emission area EA, and may include an opening exposing the other portion of the first electrode AE.

The pixel defining film PDL may be disposed in the non-emission area NEA, and may have an opening corresponding to each emission area EA. In an embodiment, the pixel defining film PDL may also be disposed at an edge portion of the emission area EA.

The pixel defining film PDL may overlap the first bank BNK1 of the light conversion layer WCL and the first light blocking pattern LBP1 of the color filter layer CFL in the third direction D3. As an example, the pixel defining film PDL may overlap the first bank BNK1 and the first light blocking pattern LBP1 in the non-emission area NEA.

In an embodiment, the pixel defining film PDL may include at least one organic layer including an organic insulating material. As an example, the pixel defining film PDL may include an organic insulating material such as a polyacrylates resin, an epoxy resin, a phenolic resin, a polyamides resin, a polyimides resin, an unsaturated polyesters resin, a polyphenyleneethers resin, a polyphenylenesulfides resin, or benzocyclobutene (BCB), but is not limited thereto.

The light emitting layer OL may be disposed on each first electrode AE. In an embodiment, the light emitting layer OL may have a shape of a continuous film formed across the emission areas EA and the non-emission area NEA. However, embodiments are not limited thereto. For example, the light emitting layer OL may also be formed individually in each emission area EA. As an example, the light emitting layers OL of the light emitting elements EL positioned in the respective emission areas EA may be formed to be separated from each other.

In an embodiment, the light emitting layer OL may emit light of a third color, for example, blue light. However, embodiments are not limited thereto. For example, the light emitting layer OL may also emit white light or the like within the spirit and the scope of the disclosure.

The light emitting layer OL may be positioned only in the display area DA, but is not limited thereto. For example, a portion of the light emitting layer OL may also be disposed in at least a portion of the non-display area NDA.

The light emitting layer OL of the light emitting element EL may include a high molecular material or a low molecular material. Light emitted from the light emitting layer OL may contribute to image display. The light emitting layer OL will be described in detail later.

The second electrode CE may be disposed on the light emitting layer OL. In an embodiment, the second electrode CE may be a common electrode shared by the pixels PX. As an example, the second electrode CE may be entirely formed on the display area DA (or a portion of the display area DA) including the emission areas EA.

In an embodiment, the display panel 110 may be a top emission-type display panel, and the second electrode CE may have semi-transmissive properties or transmissive properties. In an embodiment, the second electrode CE may include Ag, Mg, Cu, Al, Pt, Pd, Au, Ni, Nd, Ir, Cr, Li, Ca, LiF/Ca, LiF/Al, Mo, Ti or compounds or mixtures thereof such as a mixture of Ag and Mg, and may have semi-transmissive properties. In an embodiment, the second electrode CE may include tungsten oxide (WₓOₓ), titanium oxide (TiO₂), indium tin oxide (ITO), indium zinc oxide (IZO), zinc oxide (ZnO), indium tin zinc oxide (ITZO), magnesium oxide (MgO), or the like, and may have transmissive properties.

The first electrode AE, the light emitting layer OL, and the second electrode CE disposed in each emission area EA may constitute each light emitting element EL. For example, the first electrode AE, the light emitting layer OL, and the second electrode CE disposed in the first emission area EA1 may constitute a light emitting element EL (for example, a first light emitting element EL1) of the first pixel PX1. The first electrode AE, the light emitting layer OL, and the second electrode CE disposed in the second emission area EA2 may constitute a light emitting element EL (for example, a second light emitting element EL2) of the second pixel PX2. The first electrode AE, the light emitting layer OL, and the second electrode CE disposed in the third emission area EA3 may constitute a light emitting element EL (for example, a third light emitting element EL3) of the third pixel PX3.

In an embodiment, the light emitting elements EL of the pixels PX may emit light of the same color. As an example, the first light emitting element EL1, the second light emitting element EL2, and the third light emitting element EL3 may be blue organic light emitting diodes that emit blue light.

In an embodiment, the light emitting element layer LEL may further include a capping layer covering the second electrode CE. For example, the light emitting element layer LEL may further include a capping layer disposed on the second electrode CE and including at least one of an inorganic material or an organic material having light transmitting properties. The capping layer may improve viewing angle characteristics of the display panel 110 and improve external luminous efficiency.

The encapsulation layer ENL may be disposed on the light emitting element layer LEL. The encapsulation layer ENL may cover the light emitting element layer LEL in the display area DA and extend to the non-display area NDA to be in contact with the panel circuit layer PCL. The encapsulation layer ENL may block permeation of oxygen or moisture into the light emitting element layer LEL and alleviate an electrical or physical shock to the panel circuit layer PCL and the light emitting element layer LEL. In an embodiment, the encapsulation layer ENL may include a first encapsulation layer ENL1, a second encapsulation layer ENL2, and a third encapsulation layer ENL3 that are sequentially disposed on the light emitting element layer LEL.

Each of the first encapsulation layer ENL1 and the third encapsulation layer ENL3 may be an inorganic encapsulation layer including an inorganic material. As an example, each of the first encapsulation layer ENL1 and the third encapsulation layer ENL3 may include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, lithium fluoride, or the like within the spirit and the scope of the disclosure.

The second encapsulation layer ENL2 may be an organic encapsulation layer including an organic material. As an example, the second encapsulation organic film ENL2 may include an acrylic resin, a methacrylic resin, polyisoprene, a vinyl-based resin, an epoxy-based resin, a urethane-based resin, a cellulose-based resin, a perylene-based resin, or the like within the spirit and the scope of the disclosure.

The light conversion layer WCL may be disposed on the encapsulation layer ENL. In an embodiment, the light conversion layer WCL may be formed on the encapsulation layer ENL, but is not limited thereto. For example, the light conversion layer WCL may also be formed on the protective layer PRL (for example, the upper substrate SUB2) and disposed on the encapsulation layer ENL.

The light conversion layer WCL may include light transmitting members disposed in the emission areas EA and the first bank BNK1 disposed in the non-emission area NEA. The light transmitting members may include a first light transmitting member WCL1 (also referred to as a “first light conversion layer”) disposed in the first emission area EA1, a second light transmitting member WCL2 (also referred to as a “second light conversion layer”) disposed in the second emission area EA2, and a third light transmitting member TPL (also referred to as a “light transmitting layer”) disposed in the third emission area EA3. In an embodiment, the light conversion layer WCL may further include at least one second bank BNK2 disposed in each of the emission areas EA.

In an embodiment, the light conversion layer WCL may further include at least one capping layer. As an example, the light conversion layer WCL may further include a first capping layer CPL1 covering lower surfaces of the light transmitting members, the first bank BNK1, and the second banks BNK2, and a second capping layer CPL2 covering upper surfaces of the light transmitting members, the first bank BNK1, and second banks BNK2.

The first capping layer CPL1 may be disposed on the encapsulation layer ENL. The first capping layer CPL1 may be made of an inorganic material such as silicon nitride, silicon oxynitride, silicon oxide, titanium oxide, or aluminum oxide.

The first light transmitting member WCL1, the second light transmitting member WCL2, the third light transmitting member TPL, the first bank BNK1, and the second bank BNK2 may be disposed on the first capping layer CPL1.

The first light transmitting member WCL1 may convert some of light of a third color (for example, blue light) incident from the first light emitting element EL1 disposed in the first emission area EA1 into light of a first color (for example, red light). The light of the first color converted by the first light transmitting member WCL1 may be transmitted through the first color filter CF1 or the like and emitted to an upper portion of the display panel 110.

The first light transmitting member WCLI may include a first base resin BRS1 and first wavelength shifters WS1. The first base resin BRS1 may include a light transmitting organic material. For example, the first base resin BRS1 may include an epoxy-based resin, an acrylic resin, a cardo-based resin, an imide-based resin, or the like within the spirit and the scope of the disclosure. The first wavelength shifter WS1 may convert the light of the third color incident from the first light emitting element EL1 into the light of the first color. The first wavelength shifter WS1 may be a quantum dot (for example, a red quantum dot), a quantum rod, a fluorescent material, or a phosphorescent material. In an embodiment, the first light transmitting member WCL1 may further include light diffusing agents SCT such as titanium dioxide (TiO₂).

The second light transmitting member WCL2 may convert some of light of a third color (for example, blue light) incident from the second light emitting element EL2 disposed in the second emission area EA2 into light of a second color (for example, green light). The light of the second color converted by the second light transmitting member WCL2 may be transmitted through the second color filter CF2 or the like and emitted to an upper portion of the display panel 110.

The second light transmitting member WCL2 may include a second base resin BRS2 and second wavelength shifters WS2. The second base resin BRS2 may include a light transmitting organic material. For example, the second base resin BRS2 may include an epoxy-based resin, an acrylic resin, a cardo-based resin, an imide-based resin, or the like within the spirit and the scope of the disclosure. The second wavelength shifter WS2 may convert the light of the third color incident from the second light emitting element EL2 into the light of the second color. The second wavelength shifter WS2 may be a quantum dot (for example, a green quantum dot), a quantum rod, a fluorescent material, or a phosphorescent material. In an embodiment, the second light transmitting member WCL2 may further include light diffusing agents SCT such as titanium dioxide (TiO₂).

The third light transmitting member TPL may diffuse and/or transmit light of a third color (for example, blue light) incident from the third light emitting element EL3 disposed in the third emission area EA3. The light of the third color transmitted through the third light transmitting member TPL may be transmitted through the third color filter CF3 or the like and emitted to an upper portion of the display panel 110.

The third light transmitting member TPL may include a third base resin BRS3. The third base resin BRS3 may include a light transmitting organic material. For example, the third base resin BRS3 may include an epoxy-based resin, an acrylic resin, a cardo-based resin, an imide-based resin, or the like within the spirit and the scope of the disclosure. In an embodiment, the third light transmitting member TPL may further include light diffusing agents SCT such as titanium dioxide (TiO₂).

The first bank BNK1 may be disposed in the non-emission area NEA to partition or define the emission areas EA where light transmitting members are provided. For example, the first bank BNK1 may include the openings BOPN (see FIG. 9) corresponding to the emission areas EA of the pixels PX, and surround the emission areas EA.

In an embodiment, the first bank BNK1 may be formed to have a relatively great thickness in order to provide spaces where the light transmitting members are formed. As an example, a thickness of the first bank BNK1 may be in a range of about 1 μm to about 10 μm, but is not limited thereto.

In an embodiment, the first bank BNK1 may include an organic insulating material (for example, an acrylic resin, an epoxy resin, a phenolic resin, a polyamide resin, a polyimide resin, or other organic insulating materials). In an embodiment, the first bank BNK1 may further include a light blocking material. As an example, the first bank BNK1 may include a dye or a pigment (for example, an inorganic black pigment such as carbon black or an organic black pigment) having light blocking properties. Accordingly, the first bank BNK1 may have light blocking properties.

The second bank BNK2 may be disposed in each of the emission areas EA so as to be separated from the first bank BNK1. The second bank BNK2 may constitute the second light blocking pattern LBP2 in each emission area EA.

In an embodiment, the second bank BNK2 may be formed simultaneously with the first bank BNK1, and may include the same material as the first bank BNK1. As an example, the second bank BNK2 may include an organic insulating material and a light blocking material. In an embodiment, the second bank BNK2 may be formed to have the same height as the first bank BNK1, but is not limited thereto.

In an embodiment, each second light blocking pattern LBP2 may include at least one of a first pattern LBP2a (for example, a lower pattern) disposed in the light conversion layer WCL and a second pattern LBP2b (for example, an upper pattern) disposed above the light conversion layer WCL (for example, in the color filter layer CFL or between the color filter layer CFL and the light conversion layer WCL). In case that the second light blocking pattern LBP2 may include the first pattern LBP2a and the second pattern LBP2b, the first pattern LBP2a and the second pattern LBP2b may overlap each other at a position where each second light blocking pattern LBP2 is provided.

In an embodiment, the first pattern LBP2a of the second light blocking pattern LBP2 may include the second bank BNK2. In an embodiment, the second pattern LBP2b of the second light blocking pattern LBP2 may include color filters CF of at least two colors overlapping each other at the position where each second light blocking pattern LBP2 is provided.

The second capping layer CPL2 may be disposed on the first light transmitting member WCL1, the second light transmitting member WCL2, the third light transmitting member TPL, the first bank BNK1, and the second bank BNK2. The second capping layer CPL2 may protect the light transmitting members, the first bank BNK1, and the second bank BNK2 of the light conversion layer WCL from moisture, foreign substances, or the like within the spirit and the scope of the disclosure. In an embodiment, the second capping layer CPL2 may include an inorganic material. In an embodiment, the second capping layer CPL2 may include the same material as the first capping layer CPL1, but is not limited thereto.

The color filter layer CFL may be disposed on the second capping layer CPL2. In an embodiment, the light conversion layer WCL and the color filter layer CFL may be formed on different substrate members (for example, the lower substrate SUB1 and the upper substrate SUB2), respectively, and coupled or connected to each other so as to face each other, and the filler FIL may be disposed between the light conversion layer WCL and the color filter layer CFL.

The filler FIL may fill a space between the light conversion layer WCL and the color filter layer CFL. The filler FIL may be made of a material whose extinction coefficient is substantially 0. A refractive index and the extinction coefficient are correlated to each other, and as the refractive index decreases, the extinction coefficient may also decrease. In case that the refractive index is about 1.7 or less, the extinction coefficient may substantially converge to about 0. In an embodiment, the filler FIL may be made of a material having a refractive index of about 1.7 or less, and accordingly, may prevent or minimize a phenomenon in which the light emitted from the emitting element EL is absorbed while being transmitted through the filler FIL. In an embodiment, the filler FIL may be made of an organic material having a refractive index in a range of about 1.4 to about 1.6.

The color filter layer CFL may include the color filters CF disposed in the respective emission areas EA. For example, the color filter layer CFL may include the first color filter CF1 disposed in the first emission area EA1, the second color filter CF2 disposed in the second emission area EA2, and the third color filter CF3 disposed in the emission area EA3. The color filter layer CFL may further include the first light blocking pattern LBP1 disposed in the non-emission area NEA.

The first color filter CF1 may transmit the light of the first color therethrough and absorb or block the light of the third color. For example, the first color filter CF1 may transmit the light of the first color converted by the first light transmitting member WCL1 among the light of the third color emitted from the first light emitting element EL1 therethrough, and absorb or block the light of the third color that is not converted by the first light transmitting member WCL1 among the light of the third color emitted from the first light emitting element EL1. Accordingly, the light of the first color may be emitted from the first emission area EA1. As an example, the first color filter CF1 may be a red color filter, and the red light may be emitted from the first emission area EA1.

The second color filter CF2 may transmit the light of the second color therethrough and absorb or block the light of the third color. For example, the second color filter CF2 may transmit the light of the second color converted by the second light transmitting member WCL2 among the light of the third color emitted from the second light emitting element EL2 therethrough, and absorb or block the light of the third color that is not converted by the second light transmitting member WCL2 among the light of the third color emitted from the second light emitting element EL2. Accordingly, the light of the second color may be emitted from the second emission area EA2. As an example, the second color filter CF2 may be a green color filter, and the green light may be emitted from the second emission area EA2.

The third color filter CF3 may transmit the light of the third color therethrough. For example, the third color filter CF3 may transmit the light of the third color emitted from the third light emitting element EL3 and passing through the third light transmitting member TPL therethrough. Accordingly, the light of the third color may be emitted from the third emission area EA3. As an example, the third color filter CF3 may be a blue color filter, and the blue light may be emitted from the third emission area EA3.

Each of the first, second, and third color filters CF1, CF2, and CF3 may block external light incident from the outside. For example, the first color filter CF1 may increase purity (color purity) of a color corresponding to light of a first color, which is light of a red wavelength band, by blocking light of a second color, which is light of a green wavelength band, and light of third color, which is light of a blue wavelength band, that are incident from the outside.

The first light blocking pattern LBP1 may overlap the first bank BNK1. The first light blocking pattern LBP1 may be formed as a single-layer or multilayer light blocking layer.

In an embodiment, the first light blocking pattern LBP1 may include the first color filter CF1, the second color filter CF2, and the third color filter CF3 that are disposed to overlap each other in the non-emission area NEA. As an example, the first color filter CF1, the second color filter CF2, and the third color filter CF3 disposed in the respective emission areas EA may extend to the non-emission area NEA to overlap each other, and may accordingly constitute the first light blocking pattern LBP1.

In an embodiment, the color filter layer CFL may further include the second pattern LBP2b of the second light blocking pattern LBP2. In an embodiment, the second pattern LBP2b of the second light blocking pattern LBP2 may include the first color filter CF1 and the third color filter CF3 overlapping each other in an area where each second light blocking pattern LBP2 is disposed. As an example, the second pattern LBP2b of the second light blocking pattern LBP2 disposed in each of the first emission area EA1 and the third emission area EA3 may have a structure in which the first color filter CF1 and the third color filter CF3 are stacked each other. In an embodiment, the second pattern LBP2b of the second light blocking pattern LBP2 disposed in the second emission area EA2 may have a structure in which the first color filter CF1, the second color filter CF2, and the third color filter CF3 are stacked each other.

In an embodiment, the color filter layer CFL may further include a low refraction layer LRL covering one surface (or a surface) of each of the color filters CF. For example, the low refraction layer LRL may cover one surface of each of the color filters CF facing the light emitting element layer LEL or the like within the spirit and the scope of the disclosure.

In an embodiment, the low refraction layer LRL may have a lower refractive index than the light transmitting members (for example, the first light transmitting member WCL1, the second light transmitting member WCL2, and the third light transmitting member TPL) of the light conversion layer WCL. Accordingly, total reflection of light traveling from the light transmitting members of the light conversion layer WCL to the low refraction layer LRL may be induced, such that the light may be recycled, and light efficiency of the pixels PX may be increased.

In an embodiment, a refractive index of the low refraction layer LRL may be about 1.3 or less. In case that the refractive index of the low refraction layer LRL is about 1.3 or less, a difference in refractive index between the light transmitting members of the light conversion layer WCL and the low refraction layer LRL is great, such that the total reflection of the light may sufficiently occur. The low refraction layer LRL may compensate for a step caused by the first light blocking pattern LBP1 and the second light blocking patterns LBP2 of the color filter layer CFL to planarize a surface of the color filter layer CFL.

The protective layer PRL may be disposed on the substrate SUB and cover elements (for example, the panel circuit layer PCL, the light emitting element layer LEL, the encapsulation layer ENL, the light conversion layer WCL, and/or the color filter layer CFL) disposed on the substrate SUB. In an embodiment, the protective layer PRL may be the upper substrate SUB2 on which the color filter layer CFL is formed.

The protective layer PRL may be a rigid or flexible substrate or film. In an embodiment, the protective layer PRL may include an insulating material such as glass, may have rigid characteristics, and may not be bent. By way of example, the protective layer PRL may include polyimide or other insulating materials, may have flexible characteristics so as to be capable of being deformed, for example, bent, folded, or rolled, and may or may not be bent.

According to embodiments, reflection of external light may be blocked or reduced by disposing at least one second light blocking pattern LBP2 in each of the emission areas EA. For example, first reflected light L1 reflected from the first electrode AE of the light emitting element layer LEL may be blocked by the first pattern LBP2a of the second light blocking pattern LBP2 (for example, the second bank BNK2), and second reflected light L2 reflected from the light conversion layer WCL may be blocked by the first pattern LBP2a of the second light blocking pattern LBP2 (for example, a multilayer film including the first color filter CF1 and the third color filter CF3).

The second light blocking pattern LBP2 may be formed to have a size small enough to not significantly reduce an aperture ratio of each pixel PX (or an area or a ratio of the emission area EA). In an embodiment, at least one of the number, positions, and sizes of the second light blocking patterns LBP2 disposed in each emission area EA may be adjusted or determined in consideration of at least one of the aperture ratio, light efficiency, luminance, and external light reflectivity of each pixel PX. Accordingly, it is possible to reduce the external light reflectivity while appropriately securing the aperture ratio and the luminance of each pixel PX.

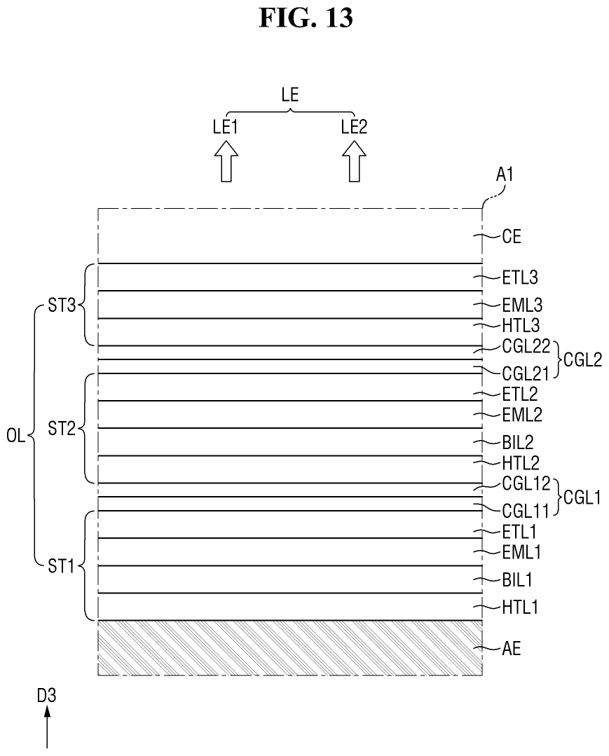

FIG. 13 is an enlarged view of area Al of FIG. 10. For example, FIG. 13 illustrates the light emitting layer OL according to an embodiment in detail.

Referring to FIGS. 10 to 13, the light emitting layer OL may have a structure in which light emitting material layers are disposed to overlap each other, for example, a tandem structure. In an embodiment, the light emitting layer OL may include a first stack ST1 including a first light emitting material layer EML1, a second stack ST2 positioned on the first stack ST1 and including a second light emitting material layer EML2, a third stack ST3 positioned on the second stack ST2 and including a third light emitting material layer EML3, a first charge generating layer CGL1 positioned between the first stack ST1 and the second stack ST2, and a second charge generating layer CGL2 positioned between the second stack ST2 and the third stack ST3. The first stack ST1, the second stack ST2, and the third stack ST3 may overlap each other.

The first light emitting material layer EML1, the second light emitting material layer EML2, and the third light emitting material layer EML3 may overlap each other. In an embodiment, the first light emitting material layer EML1, the second light emitting material layer EML2, and the third light emitting material layer EML3 may all emit light of a third color, for example, blue light. For example, each of the first light emitting material layer EML1, the second light emitting material layer EML2, and the third light emitting material layer EML3 may be a blue light emitting layer, and may include an organic material.

In an embodiment, at least one of the first light emitting material layer EML1, the second light emitting material layer EML2, and the third light emitting material layer EML3 may emit first blue light having a first peak wavelength, and at least another of the first light emitting material layer EML1, the second light emitting material layer EML2, and the third light emitting material layer EML3 may emit second blue light having a second peak wavelength different from the first peak wavelength. In an embodiment, at least one of the first light emitting material layer EML1, the second light emitting material layer EML2, and the third light emitting material layer EML3 may emit first blue light having a first peak wavelength, and the others of the first light emitting material layer EML1, the second light emitting material layer EML2, and the third light emitting material layer EML3 may emit second blue light having a second peak wavelength. For example, emitted light LE finally emitted from the light emitting layer OL may be mixed light in which a first component LE1 and a second component LE2 are mixed with each other, the first component LE1 may be the first blue light having the first peak wavelength, and the second component LE2 may be the second blue light having the second peak wavelength.

In an embodiment, a range of one of the first peak wavelength and the second peak wavelength may be about 440 nm or more and less than about 460 nm, and a range of the other of the first peak wavelength and the second peak wavelength may be about 460 nm or more and about 480 nm or less. However, the range of the first peak wavelength and the range of the second peak wavelength are not limited thereto. For example, both of the range of the first peak wavelength and the range of the second peak wavelength may also include about 460 nm. In an embodiment, any one of the first blue light and the second blue light may be light of a deep blue color, and the other of the first blue light and the second blue light may be light of a sky blue color.

In an embodiment, the emitted light LE emitted from the light emitting layer OL may be blue light, and may include a long-wavelength component and a short-wavelength component. Accordingly, the light emitting layer OL may emit blue light having a broader emission peak as the emitted light LE. Therefore, there is an advantage that color visibility at a side viewing angle may be improved compared to a display panel 100 using other light emitting elements emitting blue light having a sharper emission peak.

In an embodiment, each of the first light emitting material layer EML1, the second light emitting material layer EML2, and the third light emitting material layer EML3 may include a host and a dopant. The host may be tris (8-hydroxyquinolino) aluminum (Alq₃), 4,4′-bis(N-carbazolyl)-1,1′-biphenyl (CBP), poly(n-vinylcabazole) (PVK), 9,10-di(naphthalene-2-yl)anthracene (ADN), 4,4′,4″-tris(carbazol-9-yl)-triphenylamine (TCTA), 1,3,5-tris(N-phenylbenzimidazole-2-yl)benzene (TPBi), 3-tert-butyl-9,10-di(naphth-2-yl)anthracene (TBADN), distyryl arylene (DSA), 4,4′-bis(9-carbazolyl)-2,2″-dimethyl-biphenyl (CDBP), 2-methyl-9,10-bis(naphthalen-2-yl)anthracene (MADN), or the like, but is not limited thereto.

In an embodiment, each of the first light emitting material layer EML1, the second light emitting material layer EML2, and the third light emitting material layer EML3 may include a fluorescent material including any one selected from the group consisting of spiro-DPVBi, spiro-6P, distyryl-benzene (DSB), distyryl-arylene (DSA), a polyfluorene (PFO)-based polymer, and a poly (p-phenylene vinylene)-based polymer. In an embodiment, each of the first light emitting material layer EML1, the second light emitting material layer EML2, and the third light emitting material layer EML3 may include a phosphorescent material including an organometallic complex such as (4,6-F2ppy)2Irpic. The first light emitting material layer EML1, the second light emitting material layer EML2, and the third light emitting material layer EML3 may include materials other than the described materials.

As described above, at least one of the first light emitting material layer EML1, the second light emitting material layer EML2, and the third light emitting material layer EML3 emits blue light of a wavelength band different from that of at least another of the first light emitting material layer EML1, the second light emitting material layer EML2, and the third light emitting material layer EML3. In an embodiment, in order to emit blue light of different wavelength bands, the first light emitting material layer EML1, the second light emitting material layer EML2, and the third light emitting material layer EML3 may include the same material and a method of adjusting a resonance distance may be used. By way of example, in order to emit blue light of different wavelength bands, at least one of the first light emitting material layer EML1, the second light emitting material layer EML2, and the third light emitting material layer EML3 and at least another of the first light emitting material layer EML1, the second light emitting material layer EML2, and the third light emitting material layer EML3 may include different materials.

However, embodiments are not limited thereto. For example, the blue light emitted by each of the first light emitting material layer EML1, the second light emitting material layer EML2, and the third light emitting material layer EML3 may have a peak wavelength in a range of about 440 nm to about 480 nm, and the first light emitting material layer EML1, the second light emitting material layer EML2, and the third light emitting material layer EML3 may be made of the same material.

In an embodiment, at least one of the first light emitting material layer EML1, the second light emitting material layer EML2, and the third light emitting material layer EML3 may emit first blue light having a first peak wavelength, another of the first light emitting material layer EML1, the second light emitting material layer EML2, and the third light emitting material layer EML3 may emit second blue light having a second peak wavelength different from the first peak wavelength, and the other of the first light emitting material layer EML1, the second light emitting material layer EML2, and the third light emitting material layer EML3 may emit third blue light having a third peak wavelength different from the first peak wavelength and the second peak wavelength.

In an embodiment, a range of any one of the first peak wavelength, the second peak wavelength, and the third peak wavelength may be about 440 nm or more and less than about 460 nm. A range of another of the first peak wavelength, the second peak wavelength, and the third peak wavelength may be about 460 nm or more and less than about 470 nm, and a range of the other of the first peak wavelength, the second peak wavelength, and the third peak wavelength may be about 470 nm or more and about 480 nm or less.

In an embodiment, the emitted light LE emitted from the light emitting layer OL may be blue light, and may include a long-wavelength component, a mid-wavelength component, and a short-wavelength component. Accordingly, the light emitting layer OL may emit blue light having a broader emission peak as the emitted light LE, and may improve color visibility at a side viewing angle of the display panel 110.

The light emitting element EL having the tandem structure described above has an advantage that light efficiency may be increased and an advantage that a lifespan of the display device 100 may be increased, compared to a light emitting element having a non-tandem structure.

In an embodiment, at least one of the first light emitting material layer EML1, the second light emitting material layer EML2, and the third light emitting material layer EML3 may emit the light of the third color, for example, the blue light, and at least another of the first light emitting material layer EML1, the second light emitting material layer EML2, and the third light emitting material layer EML3 may emit the light of the second color, for example, the green light. A range of a peak wavelength of the blue light emitted by at least one of the first light emitting material layer EML1, the second light emitting material layer EML2, and the third light emitting material layer EML3 may be about 440 nm or more to about 480 nm or less or about 460 nm or more to about 480 nm or less. A range of a peak wavelength of the green light emitted by at least another of the first light emitting material layer EML1, the second light emitting material layer EML2, and the third light emitting material layer EML3 may be about 510 nm to about 550 nm.

As an example, any one of the first light emitting material layer EML1, the second light emitting material layer EML2, and the third light emitting material layer EML3 may be a green light emitting layer emitting the green light, and the others of the first light emitting material layer EML1, the second light emitting material layer EML2, and the third light emitting material layer EML3 may be blue light emitting layers emitting the blue light. In case that the others of the first light emitting material layer EML1, the second light emitting material layer EML2, and the third light emitting material layer EML3 may be the blue light emitting layers, ranges of peak wavelengths of the blue light emitted by the two blue light emitting layers may be the same as or different from each other.

In an embodiment, the emitted light LE emitted from the light emitting layer OL may be mixed light in which a first component LE1, which is blue light, and a second component LE2, which is green light, are mixed with each other. For example, in case that the first component LE1 is light of a deep blue color and the second component LE2 is green light, the emitted light LE may be light of a sky blue color. Similar to the above-described embodiments, the emitted light LE emitted from the light emitting layer OL is mixed light of the blue light and the green light, and may include a long-wavelength component and a short-wavelength component. Accordingly, the light emitting layer OL may emit blue light having a broader emission peak as the emitted light LE, and may improve color visibility at a side viewing angle. In case that the second component LE2 of the emitted light LE is the green light, a green light component of the light provided from the display device 100 to the outside may be complemented, and accordingly, color reproducibility of the display device 100 may be improved.

In an embodiment, the green light emitting layer of the first light emitting material layer EML1, the second light emitting material layer EML2, and the third light emitting material layer EML3 may include a host and a dopant. The host of the green light emitting layer may be tris (8-hydroxyquinolino) aluminum (Alq₃), 4,4′-bis(N-carbazolyl)-1,1′-biphenyl (CBP), poly(n-vinylcabazole) (PVK), 9,10-di(naphthalene-2-yl) anthracene (ADN), 4,4′,4″-tris(carbazol-9-yl)-triphenylamine (TCTA), 1,3,5-tris(N-phenylbenzimidazole-2-yl)benzene (TPBi), 3-tert-butyl-9,10-di(naphth-2-yl)anthracene (TBADN), distyryl arylene (DSA), 4,4′-bis(9-carbazolyl)-2,2″-dimethyl-biphenyl (CDBP), or 2-methyl-9,10-bis(naphthalen-2-yl)anthracene (MADN), but is not limited thereto. The dopant of the green light emitting layer is a fluorescent material including tris-(8-hydroyquinolato) aluminum(III) (Alq₃) or a phosphorescent material, and may be fac tris(2-phenylpyridine)iridium (Ir(ppy)₃), bis(2-phenylpyridine)(acetylacetonate)iridium(III) (Ir(ppy)₂(acac)), tris[2-(p-tolyl)pyridine]iridium (III) (Ir(mppy)₃), or the like, but is not limited thereto.

The first charge generating layer CGL1 may be positioned between the first stack ST1 and the second stack ST2. The first charge generating layer CGL1 may inject charges into each light emitting layer OL. The first charge generating layer CGL1 may adjust charge balance between the first stack ST1 and the second stack ST2. The first charge generating layer CGL1 may include an n-type charge generating layer CGL11 and a p-type charge generating layer CGL12. The p-type charge generating layer CGL12 may be disposed on the n-type charge generating layer CGL11, and may be positioned between the n-type charge generating layer CGL11 and the second stack ST2.

The first charge generating layer CGL1 may have a structure in which the n-type charge generating layer CGL11 and the p-type charge generating layer CGL12 are in contact with each other. The n-type charge generating layer CGL11 may be more adjacent to the first electrode AE of the light emitting element EL than the p-type charge generating layer CGL12 is. The p-type charge generating layer CGL12 may be more adjacent to the second electrode CE of the light emitting element EL than the n-type charge generating layer CGL11 is. The n-type charge generating layer CGL11 may supply electrons to the first light emitting material layer EMLI adjacent to the first electrode AE, and the p-type charge generating layer CGL12 may supply holes to the second light emitting material layer EML2 included in the second stack ST2. The first charge generating layer CGL1 may be disposed between the first stack ST1 and the second stack ST2 and provide charges to the light emitting material layers of the first and second stacks to increase luminous efficiency of the light emitting element EL and reduce a driving voltage of the light emitting element EL.

The first stack ST1 may be positioned on the first electrodes AE of the light emitting elements EL disposed in the emission areas EA. The first stack ST1 may further include a first hole transporting layer HTL1, a first electron blocking layer BIL1, and a first electron transporting layer ETL1.

The first hole transporting layer HTL1 may be positioned on the first electrodes AE of the light emitting elements EL. The first hole transporting layer HTL1 may facilitate transport of holes and include a hole transporting material. The hole transporting material may include carbazole-based derivatives such as N-phenylcarbazole and polyvinylcarbazole, fluorene-based derivatives, triphenylamine-based derivatives such as N,N′-bis(3-methylphenyl)-N,N′-diphenyl-[1,1-biphenyl]-4,4′-diamine (TPD) and 4,4′,4″-tris(N-carbazolyl)triphenylamine (TCTA), N,N′-di(1-naphthyl)-N,N′-diphenylbenzidine (NPB), 4,4′-cyclohexylidene bis[N,N-bis(4-methylphenyl)benzenamine] (TAPC), and the like, but is not limited thereto.

The first electron blocking layer BIL1 may be positioned on the first hole transporting layer HTL1. For example, the first electron blocking layer BIL1 may be positioned between the first hole transporting layer HTL1 and the first light emitting material layer EML1. The first electron blocking layer BIL1 may include a hole transporting material and a metal or a metal compound so as to prevent electrons generated in the first light emitting material layer EML1 from crossing (intersecting) over into the first hole transporting layer HTL1. In an embodiment, each of the first hole transporting layer HTL1 and the first electron blocking layer BIL1 may also be formed as a single layer in which respective materials are mixed with each other.

The first electron transporting layer ETL1 may be positioned on the first light emitting material layer EML1. For example, the first electron transporting layer ETL1 may be positioned between the first charge generating layer CGL1 and the first light emitting material layer EML1. In an embodiment, the first electron transporting layer ETLI may include an electron transporting material such as tris(8-hydroxyquinolinato)aluminum (Alq₃), 1,3,5-tri(1-phenyl-1H-benzo[d]imidazol-2-yl)phenyl (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq2), 9,10-di(naphthalene-2-yl)anthracene (ADN), and mixtures thereof, but the electron transporting material is not limited thereto.

The second stack ST2 may be positioned on the first charge generating layer CGL1. The second stack ST2 may further include a second hole transporting layer HTL2, a second electron blocking layer BIL2, and a second electron transporting layer ETL2.

The second hole transporting layer HTL2 may be positioned on the first charge generating layer CGL1. The second hole transporting layer HTL2 may be made of the same material as the first hole transporting layer HTL1 or may include one or more materials selected from the materials described as the material included in the first hole transporting layer HTL1. The second hole transporting layer HTL2 may be formed as a single layer or multiple layers.

The second electron blocking layer BIL2 may be positioned on the second hole transporting layer HTL2. For example, the second electron blocking layer BIL2 may be positioned between the second hole transporting layer HTL2 and the second light emitting material layer EML2. The second electron blocking layer BIL2 may be made of the same material as the first electron blocking layer BIL1 and may have the same structure as the first electron blocking layer BIL1 or may include one or more materials selected from the materials described as the material included in the first electron blocking layer BIL1.

The second electron transporting layer ETL2 may be positioned on the second light emitting material layer EML2. For example, the second electron transporting layer ETL2 may be positioned between the second charge generating layer CGL2 and the second light emitting material layer EML2. The second electron transporting layer ETL2 may be made of the same material as the first electron transporting layer ETL1 and may have the same structure as the first electron transporting layer ETL1 or may include one or more materials selected from the materials described as the material included in the first electron transporting layer ETL1. The second electron transporting layer ETL2 may be formed as a single layer or multiple layers.

The second charge generating layer CGL2 may be positioned on the second stack ST2. For example, the second charge generating layer CGL2 may be positioned between the second stack ST2 and the third stack ST3. The second charge generating layer CGL2 may have the same structure as the first charge generating layer CGL1. For example, the second charge generating layer CGL2 may include an n-type charge generating layer CGL21 and a p-type charge generating layer CGL22. The p-type charge generating layer CGL22 may be disposed on the n-type charge generating layer CGL21.

The second charge generating layer CGL2 may have a structure in which the n-type charge generating layer CGL21 and the p-type charge generating layer CGL22 are in contact with each other. The first charge generating layer CGL1 and the second charge generating layer CGL2 may be made of the same material or different materials.

The third stack ST3 may be positioned on the second charge generating layer CGL2. The third stack ST3 may further include a third hole transporting layer HTL3 and a third electron transporting layer ETL3.

The third hole transporting layer HTL3 may be positioned on the second charge generating layer CGL2. The third hole transporting layer HTL3 may be made of the same material as the first hole transporting layer HTL1 or may include one or more materials selected from the materials described as the material included in the first hole transporting layer HTL1. The third hole transporting layer HTL3 may be formed as a single layer or multiple layers. In case that the third hole transporting layer HTL3 is formed as the multiple layers, respective layers may include different materials.

The third electron transporting layer ETL3 may be positioned on the third light emitting material layer EML3. For example, the third electron transporting layer ETL3 may be positioned between the second electrode CE of the light emitting element EL and the third light emitting material layer EML3. The third electron transporting layer ETL3 may be made of the same material as the first electron transporting layer ETL1 and may have the same structure as the first electron transporting layer ETL1 or may include one or more materials selected from the materials described as the material included in the first electron transporting layer ETL1. The third electron transporting layer ETL3 may be formed as a single layer or multiple layers. In case that the third electron transporting layer ETL3 is formed as the multiple layers, respective layers may include different materials.

Although not illustrated in FIG. 13, a hole injection layer may be further positioned between the first electrode AE of each of the light emitting elements EL and the first stack ST1, between the first charge generating layer CGLI and the second stack ST2, or between the second charge generating layer CGL2 and the third stack ST3. The hole injection layer may serve to more smoothly inject holes into the first light emitting material layer EML1, the second light emitting material layer EML2, and the third light emitting material layer EML3. In an embodiment, the hole injection layer may be made of one or more selected from the group consisting of cupper phthalocyanine (CuPc), poly(3,4)-ethylenedioxythiophene (PEDOT), polyaniline (PANI), and N,N-dinaphthyl-N,N′-diphenyl benzidine (NPD), but is not limited thereto.

An electron injection layer may be further positioned between the first stack ST1 and the first charge generating layer CGL1, between the second stack ST2 and the second charge generating layer CGL2, or between the third electron transporting layer ETL3 and the second electrode CE of the light emitting elements EL. The electron injection layer may serve to smoothly inject electrons, and may be made of tris(8-hydroxyquinolino) aluminum(Alq₃), PBD, TAZ, spiro-PBD, BAlq, or SAlq, but is not limited thereto. The electron injection layer may include a metal halide compound, for example, one or more selected from the group consisting of MgF₂, LiF, NaF, KF, RbF, CsF, FrF, LiI, Nal, KI, RbI, CsI, FrI, and CaF₂, but is not limited thereto. The electron injection layer may include a lanthanum-based material such as Yb, Sm, or Eu. By way of example, the electron injection layer may include both a metal halide material and a lanthanum-based material such as RbI:Yb or KI:Yb. In case that the electron injection layer may include both the metal halide material and the lanthanum-based material, the electron injection layer may be formed by co-depositing the metal halide material and the lanthanum-based material.

In an embodiment, the light emitting layer OL may not include a red light emitting material layer, and accordingly, may not emit the light of the third color such as the red light. For example, the emitted light LE may not include a light component having a peak wavelength in a range of about 610 nm to about 650 nm, and may include only a light component having a peak wavelength in a range of about 440 nm to about 550 nm.

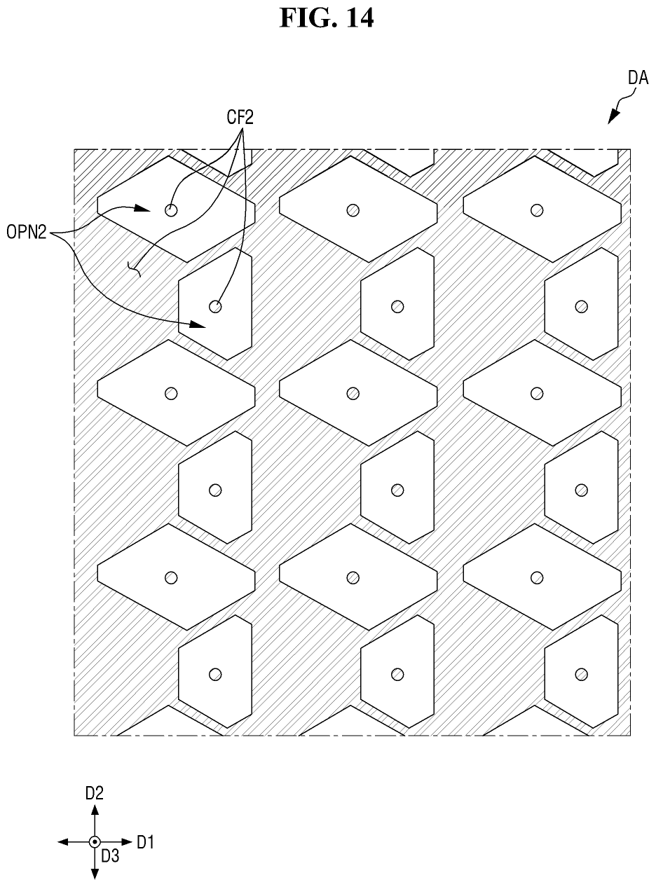

FIG. 14 is a schematic plan view illustrating a second color filter CF2 according to an embodiment. For example, FIG. 14 illustrates a modified example of the second color filter CF2 of FIGS. 4 and 7.

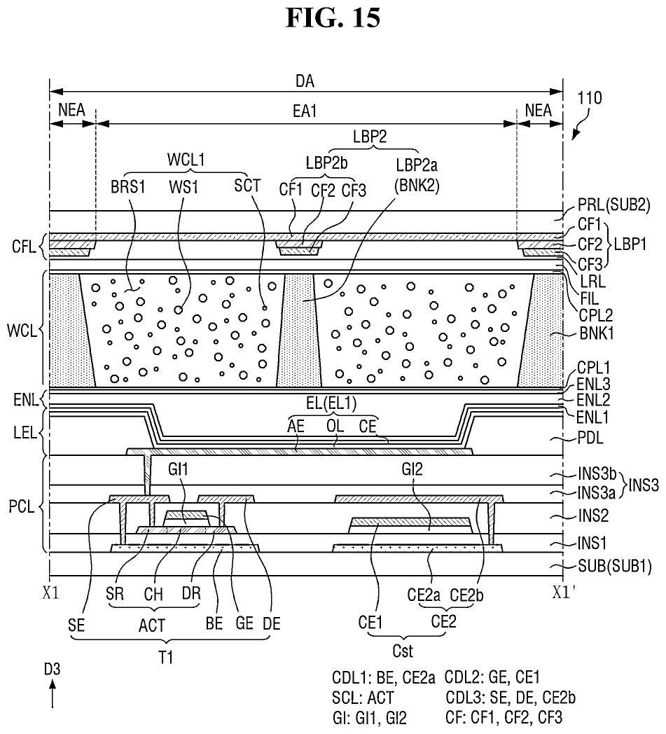

FIG. 15 is a schematic cross-sectional view illustrating the display panel 100 according to an embodiment. For example, FIG. 15 illustrates a cross section of a first pixel PX1 including the second color filter CF2 of FIG. 14 (for example, a cross section of a first pixel PX according to an embodiment corresponding to line X1-X1′ of FIG. 4), and illustrates a modified example of the second light blocking pattern LBP2 of FIG. 10. In describing embodiments to be disclosed below, an overlapping description of components that are substantially the same as or similar to those of at least one embodiment described above may be omitted.

Referring to FIGS. 14 and 15, each second light blocking pattern LBP2 may further include the second color filter CF2. As an example, the second pattern LBP2b of the second light blocking pattern LBP2 may have a triple-layer structure including the first color filter CF1, the second color filter CF2, and the third color filter CF3 overlapping each other at a position where each second light blocking pattern LBP2 is provided. Accordingly, reflected light (for example, the second reflected light L2 in FIG. 10) incident on the second light blocking pattern LBP2 may be effectively blocked.

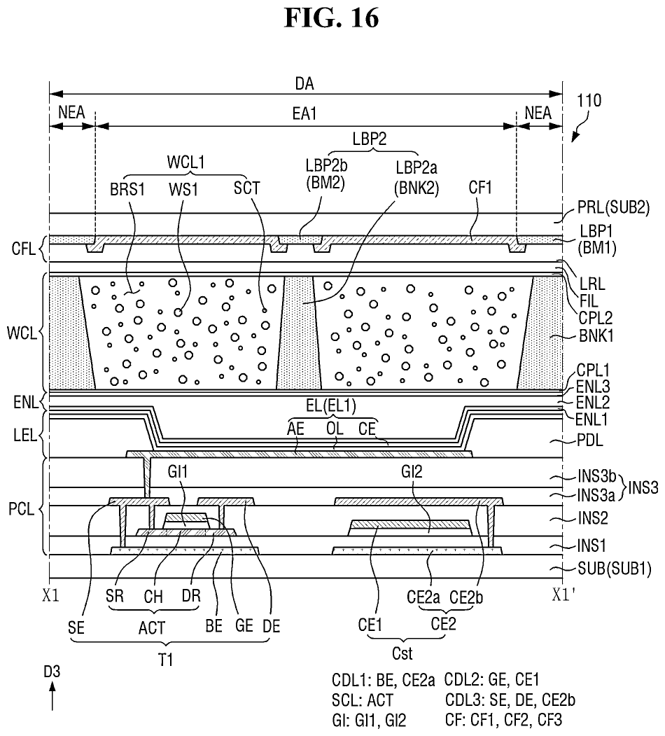

FIG. 16 is a schematic cross-sectional view illustrating a display panel 110 according to an embodiment. For example, FIG. 16 illustrates a cross section of a first pixel PX according to an embodiment corresponding to line X1-X1′ of FIG. 4, and illustrates an embodiment different from the above-described embodiments in relation to the color filter layer CFL.

Referring to FIG. 16, the first color filter CF1 may be individually patterned to correspond to the first emission area EA1. Similarly, the second color filter CF2 may be individually patterned to correspond to the second emission area EA2, and the third color filter CF3 may be individually patterned to correspond to the third emission area EA3.

The first light blocking pattern LBP1 may include a first black matrix pattern BM1 disposed in the non-emission area NEA. The second pattern LBP2b of the second light blocking pattern LBP2 may include a second black matrix pattern BM2 disposed in an area of each second light blocking pattern LBP2. For example, at least one second light blocking pattern LBP2 including the second black matrix pattern BM2 may be disposed in each of the first emission area EA1, the second emission area EA2, and the third emission area EA.

In an embodiment, the first black matrix pattern BM1 and the second black matrix pattern BM2 may be patterns formed simultaneously using the same material, and may be separated from each other. For example, the second black matrix pattern BM2 may be disposed to be separated from the first black matrix pattern BM1 in the color filter layer CFL in which the first black matrix pattern BM1 is provided, and may include the same material as the first black material pattern BM1. In an embodiment, the first black matrix pattern BM1 and the second black matrix pattern BM2 may be formed as organic films made of an acryl resin, an epoxy resin, a phenolic resin, a polyamide resin, a polyimide resin, or the like, and may include an inorganic black pigment such as carbon black or an organic black pigment.

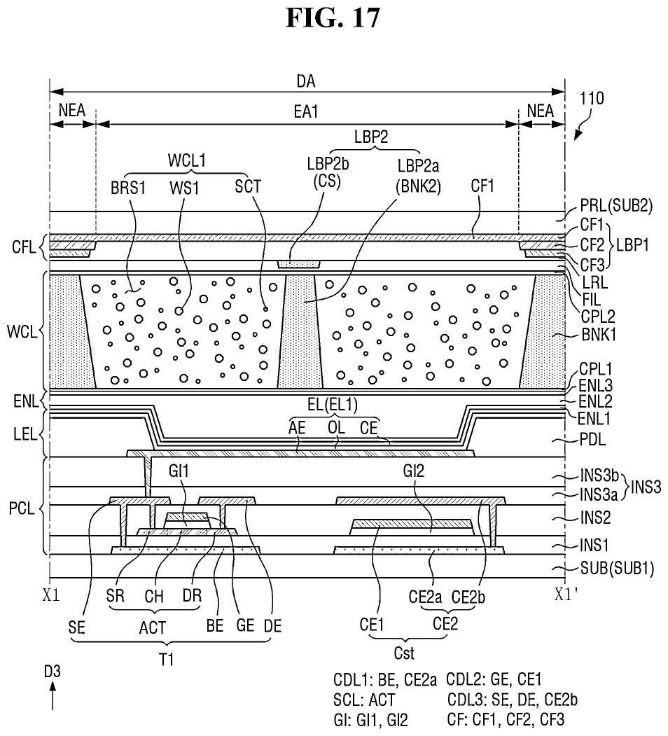

FIG. 17 is a schematic cross-sectional view illustrating a display panel 110 according to an embodiment. For example, FIG. 17 illustrates a cross section of a first pixel PX according to an embodiment corresponding to line X1-X1′ of FIG. 4, and illustrates an embodiment different from the above-described embodiments in relation to the second light blocking pattern LBP2.

Referring to FIG. 17, each second light blocking pattern LBP2 may include a colored spacer pattern CS (for example, a column spacer pattern colored in black) disposed on one surface of the low refraction layer LRL. For example, the second pattern LBP2b of the second light blocking pattern LBP2 may include a colored spacer pattern CS provided in an area where each second light blocking pattern LBP2 is disposed, on one surface of the low refraction layer LRL facing the light conversion layer WCL.

In an embodiment, the second light blocking patterns LBP2 disposed in the second emission area EA2 and the third emission area EA3 may also have substantially the same structure as the second light blocking pattern LBP2 disposed in the first emission area EA1. For example, each of the second light blocking patterns LBP2 disposed in the second emission area EA2 and the third emission area EA3 may include a colored spacer pattern CS.

In an embodiment, color filters CF may not be disposed to overlap each other in the area where each second light blocking pattern LBP2 is disposed. For example, a color filter CF corresponding to an emission color of a corresponding pixel PX may be disposed but color filters CF of different colors may not be disposed, at a position where each second light blocking pattern LBP2 is provided in the emission area EA of each pixel PX.

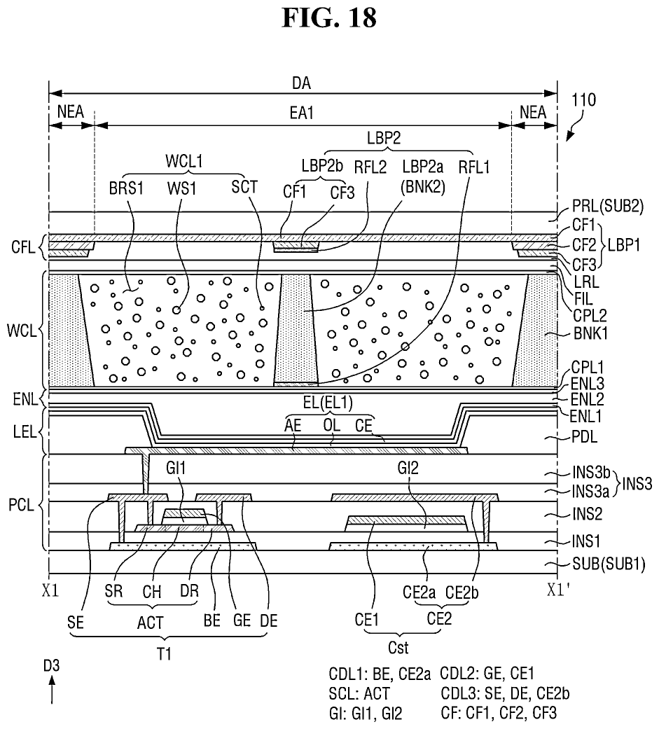

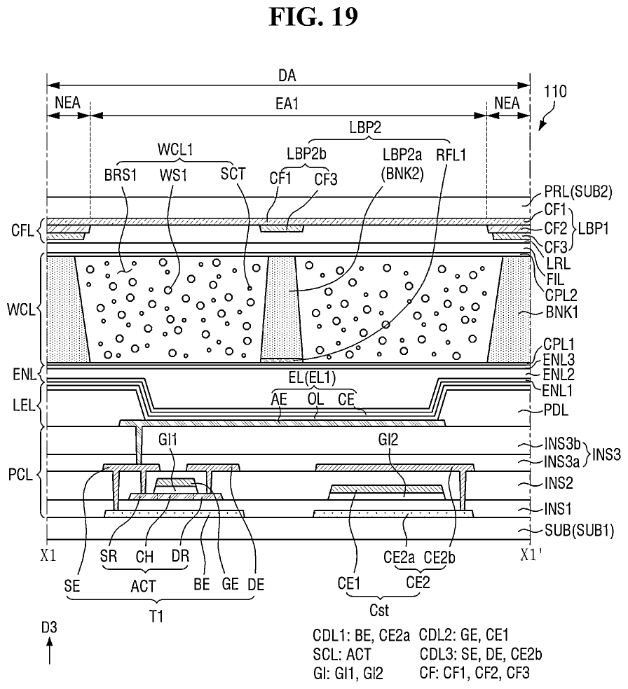

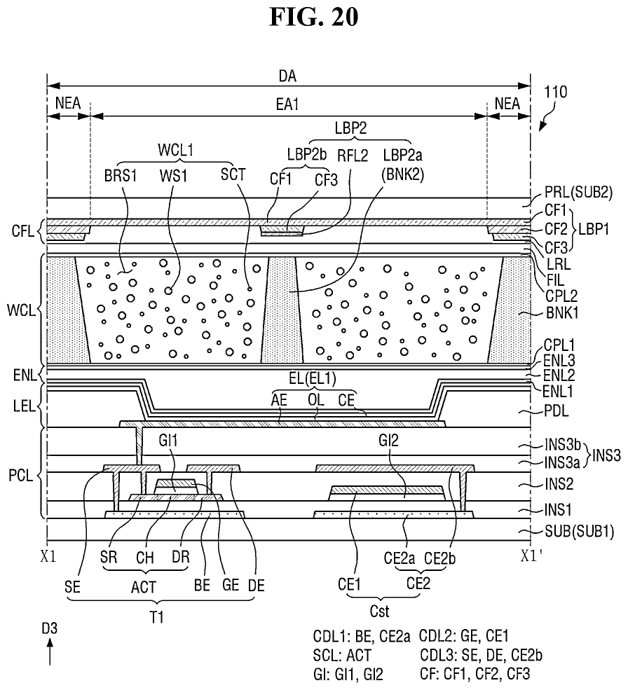

FIG. 18 is a schematic cross-sectional view illustrating a display panel 110 according to an embodiment. FIG. 19 is a schematic cross-sectional view illustrating a display panel 110 according to an embodiment. FIG. 20 is a schematic cross-sectional view illustrating a display panel 110 according to an embodiment. For example, FIGS. 18 to 20 illustrate cross sections of first pixels PX according to respective embodiments corresponding to line X1-X1′ of FIG. 4, and illustrate embodiments different from the above-described embodiments in relation to the second light blocking pattern LBP2.

Referring to FIGS. 18 to 20, each second light blocking pattern LBP2 may further include at least one reflective film. For example, the second light blocking pattern LBP2 may further include a first reflective film RFL1 disposed on one surface (for example, a lower surface) of the first pattern LBP2a facing the light emitting element layer LEL and a second reflective film RFL2 disposed on one surface (for example, a lower surface) of the second pattern LBP2b facing the light emitting element layer LEL, as illustrated in FIG. 18.

In an embodiment, the second light blocking pattern LBP2 may also include only one of the first reflective film RFL1 and the second reflective film RFL2. For example, the second light blocking pattern LBP2 may include the first reflective film RFL1 but may not include the second reflective film RFL2, as illustrated in FIG. 19. By way of example, the second light blocking pattern LBP2 may not include the first reflective film RFL1 but may include the second reflective film RFL2, as illustrated in FIG. 20.

In an embodiment, the second light blocking patterns LBP2 disposed in the second emission area EA2 and the third emission area EA3 may also have substantially the same structure as the second light blocking pattern LBP2 disposed in the first emission area EA1. For example, each of the second light blocking patterns LBP2 disposed in the second emission area EA2 and the third emission area EA3 may further include at least one of a first reflective film RFL1 and a second reflective film RFL2.

The second light blocking pattern LBP2 further may include at least one of the first reflective film RFL1 and the second reflective film RFL2, and accordingly, light efficiency of the pixel PX may be increased. For example, light reflected from at least one of the first reflective film RFL1 and the second reflective film RFL2 is recirculated or recycled, such that light efficiency of the pixels PX may be improved.

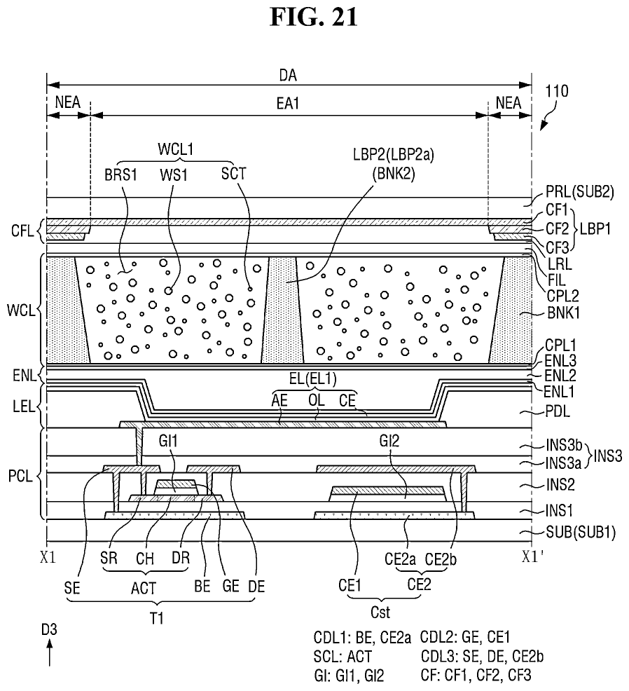

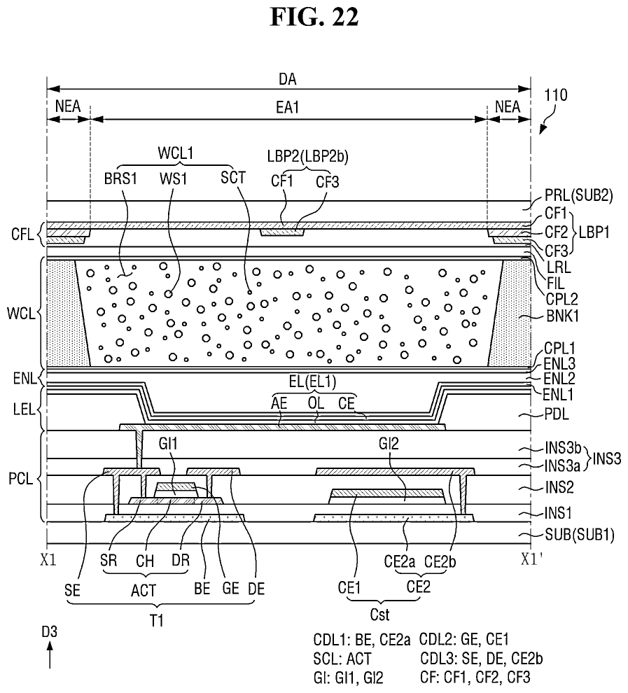

FIG. 21 is a schematic cross-sectional view illustrating a display panel 110 according to an embodiment. FIG. 22 is a schematic cross-sectional view illustrating the display panel 100 according to an embodiment. For example, FIGS. 21 and 22 illustrate cross sections of first pixels PX according to respective embodiments corresponding to line X1-X1′ of FIG. 4, and illustrate embodiments different from the above-described embodiments in relation to the second light blocking pattern LBP2.

Only the second light blocking pattern LBP2 disposed in the first emission area EA1 has been illustrated in FIGS. 21 and 22, but the second light blocking patterns LBP2 disposed in the second emission area EA2 and the third emission area EA3 may also have substantially the same structure as the second light blocking pattern LBP2 disposed in the first emission area EA1.

Referring to FIGS. 21 and 22, each second light blocking pattern LBP2 may include only one of the first pattern LBP2a and the second pattern LBP2b. For example, the second light blocking pattern LBP2 may include the first pattern LBP2a but may not the second pattern LBP2b, as illustrated in FIG. 21. By way of example, the second light blocking pattern LBP2 may not include the first pattern LBP2a but may include the second pattern LBP2b, as illustrated in FIG. 22.

Each of embodiments of FIGS. 4 to 22 may be applied alone to the display panel 110 or may be combined with at least one other embodiment. As an example, each second light blocking pattern LBP2 may include at least one of the first pattern LBP2a and the second pattern LBP2b.

Each first pattern LBP2a may include the second bank BNK2. The first reflective film RFL1 may be disposed or may not be disposed beneath each first pattern LBP2a.

Each second pattern LBP2b may have a structure in which the color filters CF of at least two colors are stacked each other, may include the second black matrix pattern BM2, or may include the colored spacer pattern CS. The second reflective film RFL2 may be disposed or may not be disposed beneath each second pattern LBP2b.

Embodiments in which the same number of second light emitting patterns LBP2 are disposed in the first emission area EA1, the second emission area EA2, and the third emission area EA3 have been illustrated in FIGS. 4 to 22, but embodiments are not limited thereto. For example, the second light blocking patterns LBP2 may be disposed only in some of the first emission area EA1, the second emission area EA2, and the third emission area EA3. By way of example, different numbers of second light blocking patterns LBP2 may be disposed in the first emission area EA1, the second emission area EA2, and/or the third emission area EA3. For example, in consideration of light efficiency, white balance, or visibility of the pixels PX, the numbers, sizes, or the like, of the second light blocking patterns LBP2 disposed in the emission areas EA may be differentiated.

As described above, the display device 100 according to embodiments may include the second light blocking patterns LBP2 disposed in at least some emission areas EA. Accordingly, external light reflectivity of the display device 100 may be reduced, and visibility of the image displayed in the display area DA may be improved.

In concluding the detailed description, those skilled in the art will appreciate that many variations and modifications can be made to the embodiments without substantially departing from the principles of the disclosure. Therefore, the disclosed embodiments are used in a generic and descriptive sense only and not for purposes of limitation.

What is claimed is:

1. A display device comprising:
a light emitting element layer including light emitting elements disposed on a substrate;
a color filter layer disposed on the light emitting element layer, the color filter layer including color filters disposed in respective emission areas and a first light blocking pattern disposed in a non-emission area surrounding the emission areas; and
second light blocking patterns disposed on the light emitting element layer and disposed in the emission areas.

2. The display device of claim 1, wherein
the second light blocking patterns are at positions spaced apart from the first light blocking pattern, and
at least one of the second light blocking patterns is disposed in each of the emission areas.

3. The display device of claim 1, wherein
the emission areas includes a first emission area emitting light of a first color, a second emission area emitting light of a second color, and a third emission area emitting light of a third color, and
the color filters include a first color filter disposed in at least the first emission area, a second color filter disposed in at least the second emission area, and a third color filter disposed in at least the third emission area.

4. The display device of claim 3, wherein the second light blocking patterns include color filters of at least two colors that overlap each other at a position where each of the second light blocking patterns is disposed.

5. The display device of claim 4, wherein
the light of the first color, the light of the second color, and the light of the third color are red light, green light, and blue light, respectively,
the first color filter, the second color filter, and the third color filter are a red color filter, a green color filter, and a blue color filter, respectively, and
each of the second light blocking patterns includes the first color filter and the third color filter.

6. The display device of claim 5, wherein each of the second light blocking patterns further includes the second color filter.

7. The display device of claim 3, wherein the first light blocking pattern includes the first color filter, the second color filter, and the third color filter that overlap each other in the non-emission area.

8. The display device of claim 1, wherein the first light blocking pattern includes a first black matrix pattern disposed in the non-emission area.

9. The display device of claim 8, wherein the second light blocking patterns include at least one second black matrix pattern disposed in each of the emission areas.

10. The display device of claim 1, wherein
the color filter layer further includes a low refraction layer covering a surface of each of the color filters facing the light emitting element layer, and
the second light blocking patterns include colored spacer patterns disposed on a surface of the low refraction layer.

11. The display device of claim 1, further comprising:
a light conversion layer disposed between the light emitting element layer and the color filter layer, the light conversion layer including light transmitting members disposed in the emission areas and a first bank disposed in the non-emission area.

12. The display device of claim 11, wherein
the second light blocking patterns include at least one second bank disposed in the light conversion layer and disposed in each of the emission areas to be separated from the first bank, and
the first bank and the second bank include a same material.

13. The display device of claim 11, wherein
the emission areas include a first emission area emitting light of a first color, a second emission area emitting light of a second color, and a third emission area emitting light of a third color, and
the light transmitting members include a first light transmitting member disposed in the first emission area, a second light transmitting member disposed in the second emission area, and a third light transmitting member disposed in the third emission area.

14. The display device of claim 13, wherein
the light emitting elements emit the light of the third color,
the first light transmitting member includes a first wavelength shifter converting the light of the third color into the light of the first color, and
the second light transmitting member includes a second wavelength shifter converting the light of the third color into the light of the second color.

15. The display device of claim 13, wherein the first light transmitting member, the second light transmitting member, and the third light transmitting member include a light diffusing agent.

16. The display device of claim 11, wherein each of the second light blocking patterns includes at least one of:
a first pattern disposed in the light conversion layer; and
a second pattern disposed in the color filter layer or between the color filter layer and the light conversion layer.

17. The display device of claim 16, wherein each of the second light blocking patterns further includes at least one of:
a first reflective film disposed on a surface of the first pattern facing the light emitting element layer; and
a second reflective film disposed on a surface of the second pattern facing the light emitting element layer.

18. A display device comprising:
a light emitting element layer including light emitting elements disposed on a substrate;
a light conversion layer disposed on the light emitting element layer, the light conversion layer including light transmitting members disposed in emission areas and a first bank disposed in a non-emission area surrounding the emission areas;
a color filter layer disposed on the light conversion layer, the color filter layer including color filters disposed in the emission areas and a first light blocking pattern disposed in the non-emission area; and
second light blocking patterns disposed in at least one of the light conversion layer and the color filter layer and disposed in the emission areas.

19. The display device of claim 18, wherein each of the second light blocking patterns includes a second bank disposed in the light conversion layer and separated from the first bank.

20. The display device of claim 18, wherein each of the second light blocking patterns includes color filters of at least two colors disposed in the color filter layer and overlapping each other and a black matrix pattern disposed in the color filter layer and separated from the first light blocking pattern or a colored spacer pattern disposed on a surface of a low refraction layer covering a surface of each of the color filters.
